(19) United States
(12) Patent Application Publication
(10) Pub. No.: US 2025/0287796 A1
(43) Pub. Date: Sep. 11, 2025

(54) DISPLAY PANEL AND ELECTRONIC DEVICE INCLUDING THE SAME

(71) Applicant: Samsung Display Co., Ltd., Yongin-si (KR)

(72) Inventors: Minki Yang, Yongin-si (KR); Wonkyu Kwak, Yongin-si (KR); Taehoon Kim, Yongin-si (KR); Jisu Na, Yongin-si (KR); Changkyu Jin, Yongin-si (KR)

(73) Assignee: Samsung Display Co., Ltd., Yongin-si (KR)

(21) Appl. No.: 19/013,379

(22) Filed: Jan. 8, 2025

(30) Foreign Application Priority Data
Mar. 6, 2024 (KR) 10-2024-0032222
Jun. 20, 2024 (KR) 10-2024-0080204

(51) Int. Cl. H10K 59/131; H10K 59/121

(52) U.S. Cl. CPC H10K 59/131; H10K 59/1213

(57) ABSTRACT

A display panel includes a first pixel circuit, a second pixel circuit, and a third pixel circuit on a substrate, each of the first pixel circuit, the second pixel circuit, and the third pixel circuit includes a first transistor including a first source region adjacent to the first channel region, and a first gate electrode, a second transistor including a second channel region and a second gate electrode, a first conductive pattern below the first channel region, and a second conductive pattern on the first gate electrode, the first source region is disposed between the first channel region and the second channel region and protrudes beyond the first conductive pattern and the second conductive pattern in the first direction in a plan view, and the first pixel circuit and the second pixel circuit are substantially symmetrical to each other with respect to an imaginary straight line.

### CROSS-REFERENCE TO RELATED APPLICATION(S)

This application claims priority to and benefits of Korean Patent Application Nos. 10-2024-0032222 and 10-2024-0080204, respectively under 35 U.S.C. § 119 filed on Mar. 6, 2024 and Jun. 20, 2024, in the Korean Intellectual Property Office, the entire contents of which are incorporated herein by reference.

### BACKGROUND

### 1. Technical Field

One or more embodiments relate to a display panel and an electronic device including the display panel.

### 2. Description of the Related Art

A display panel may include pixels. Each of the pixels may include a light-emitting diode and a pixel circuit for controlling luminance, etc. of the light-emitting diode. The pixel circuit may include transistors and capacitors, connected to wirings such as a data line, a gate line, and a voltage line.

Recently, as thicknesses and weights of display panels have decreased, display panels may be applied to various electronic devices. As display panels have been widely used, various types of display panels and electronic devices including the same have been designed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

As a display panel has a higher resolution, a distance between data lines and transistors decreases, and thus, a data signal applied to a pixel may affect surrounding pixels. One or more embodiments include a display panel for displaying a high-quality image and an electronic device including the display panel. However, the embodiments are examples and do not limit the scope of the disclosure.

Additional aspects will be set forth in part in the description which follows and, in part, will be apparent from the description, or may be learned by practice of the presented embodiments.

According to one or more embodiments, a display panel may include a first pixel circuit; a second pixel circuit; and a third pixel circuit disposed side by side along a first direction on a substrate, wherein each of the first pixel circuit, the second pixel circuit, and the third pixel circuit may include a first transistor including a first channel region, a first source region adjacent to the first channel region, and a first gate electrode disposed on the first channel region, a second transistor including a second channel region and a second gate electrode disposed on the second channel region; a first conductive pattern disposed below the first channel region; and a second conductive pattern disposed on the first gate electrode, wherein a first source region may be disposed between the first channel region and the second channel region and protrudes beyond the first conductive pattern and the second conductive pattern in the first direction in a plan view, wherein the first pixel circuit and the second pixel circuit are substantially symmetrical to each other with respect to an imaginary straight line extending in a second direction intersecting the first direction.

In an embodiment, the display panel may further include a first data line electrically connected to the first pixel circuit, a second data line electrically connected to the second pixel circuit, and a third data line electrically connected to the third pixel circuit, wherein the first transistor of the first pixel circuit and the first transistor of the second pixel circuit are disposed between the first data line and the second data line.

In an embodiment, the display panel may further include a first pixel electrode electrically connected to the first pixel circuit, a second pixel electrode electrically connected to the second pixel circuit, and a third pixel electrode electrically connected to the third pixel circuit, wherein the first pixel electrode and the second pixel electrode are disposed between the first data line and the second data line, and the third pixel electrode is disposed between the second data line and the third data line.

In an embodiment, the first pixel electrode and the second pixel electrode may be alternately disposed along the second direction.

In an embodiment, the first data line and the second data line may be spaced apart from the first pixel electrode, the second pixel electrode, and the third pixel electrode in a plan view.

In an embodiment, the display panel may further include a first voltage line overlapping the first transistor of the first pixel circuit and the first transistor of the second pixel circuit, and a second voltage line overlapping the first transistor of the third pixel circuit.

In an embodiment, the first pixel electrode and the second pixel electrode may overlap the first voltage line, and the third pixel electrode may overlap the second voltage line.

In an embodiment, the display panel may further include a third voltage line extending in the first direction and electrically connected to the first voltage line and the second voltage line, wherein the third voltage line is electrically connected to the first conductive pattern and the second conductive pattern.

In an embodiment, the display panel may further include an auxiliary voltage line extending in the second direction and disposed between the second data line and the first transistor of the third pixel circuit.

In an embodiment, the auxiliary voltage line may be substantially symmetrical to the third data line with respect to an imaginary straight line passing through a center of the third pixel electrode.

According to one or more embodiments, a display panel may include a first pixel circuit, a second pixel circuit, and a third pixel circuit disposed side by side along a first direction on a substrate, wherein each of the first pixel circuit, the second pixel circuit, and the third pixel circuit may include a first conductive layer disposed on the substrate and including a first conductive pattern, a first semiconductor layer disposed on the first conductive layer and including a first channel region, a second channel region, and a first source region disposed between the first channel region and the second channel region, a second conductive layer disposed on the first semiconductor layer and including a first gate electrode overlapping the first channel region and a second gate electrode overlapping the second channel region, and a third conductive layer disposed on the second conductive layer and including a second conductive pattern overlapping the first gate electrode, wherein the first conductive layer, the second conductive layer, and the third conductive layer include an opening portion through which the first source region is exposed in a plan view, wherein the first pixel circuit and the second pixel circuit are substantially symmetrical to each other with respect to an imaginary straight line extending in a second direction intersecting the first direction.

In an embodiment, the display panel may further include a fourth conductive layer disposed on the third conductive layer and including a first voltage line extending in the first direction and electrically connected to the second conductive pattern, and a fifth conductive layer disposed on the fourth conductive layer and including a first data line electrically connected to the first pixel circuit, a second data line electrically connected to the second pixel circuit, and a third data line electrically connected to the third pixel circuit, wherein the first gate electrode of the first pixel circuit and the first gate electrode of the second pixel circuit are disposed between the first data line and the second data line.

In an embodiment, the fifth conductive layer may further include a second voltage line overlapping the first gate electrode of the first pixel circuit and the first gate electrode of the second pixel circuit and a third voltage line extending in the second direction and overlapping the first gate electrode of the third pixel circuit, wherein the first voltage line is electrically connected to the second voltage line and the third voltage line.

In an embodiment, the first voltage line may be electrically connected to the first conductive pattern of the first pixel circuit.

In an embodiment, the display panel may further include a sixth conductive layer disposed on the fifth conductive layer and including a first pixel electrode electrically connected to the first pixel circuit, a second pixel electrode electrically connected to the second pixel circuit, and a third pixel electrode electrically connected to the third pixel circuit, wherein the first pixel electrode and the second pixel electrode are disposed between the first data line and the second data line, and the third pixel electrode is disposed between the second data line and the third data line.

In an embodiment, the first pixel electrode and the second pixel electrode may be alternately arranged along the second direction.

In an embodiment, the first data line and the second data line may be spaced apart from the first pixel electrode, the second pixel electrode, and the third pixel electrode in a plan view.

In an embodiment, the fifth conductive layer may further include an auxiliary voltage line extending in the second direction and disposed between the second data line and the first gate electrode of the third pixel circuit.

In an embodiment, the auxiliary voltage line may be substantially symmetrical to the third data line with respect to an imaginary straight line passing through a center of the third pixel electrode.

According to one or more embodiments, an electronic device may include a display panel on which a plurality of pixels are disposed, wherein the display panel may include a first pixel circuit, a second pixel circuit, and a third pixel circuit disposed side by side in a first direction on a substrate, wherein each of the first pixel circuit, the second pixel circuit, and the third pixel circuit may include a first transistor including a first channel region, a first source region, a first drain region, and a first gate electrode disposed on the first channel region, wherein the first source region and the first drain region face each other with the first channel region disposed between the first source region and the first drain region, a second transistor including a second channel region and a second gate electrode disposed on the second channel region, a first conductive pattern disposed below the first channel region, and a second conductive pattern disposed on the first gate electrode, wherein the first source region may be disposed between the first channel region and the second channel region and protrudes beyond the first conductive pattern and the second conductive pattern in the first direction in a plan view, and wherein the first pixel circuit and the second pixel circuit are substantially symmetrical to each other with respect to an imaginary straight line extending in a second direction intersecting the first direction.

Other aspects, features, and advantages of the disclosure will become more apparent from the drawings, the claims, and the detailed description.

### BRIEF DESCRIPTION OF THE DRAWINGS

The above and other aspects, features, and advantages of embodiments will be more apparent from the following description taken in conjunction with the accompanying drawings, in which:

FIG. 1 is a schematic plan view schematically illustrating a display panel, according to an embodiment;

FIG. 2 is a schematic diagram of an equivalent circuit illustrating a pixel included in a display panel, according to an embodiment;

FIGS. 3 and 4 are views for describing a flip structure of a pixel circuit, according to an embodiment;

FIG. 5 is a schematic plan view illustrating a portion of a display panel, according to an embodiment;

FIGS. 6 to 16 are schematic plan views each illustrating a portion of the display panel of FIG. 6 for each layer;

FIG. 17 is a schematic plan view illustrating a portion of a display panel, according to an embodiment;

FIG. 18 is a schematic cross-sectional view taken along line I-I′ of the display panel of FIG. 17;

FIG. 19 is a schematic plan view illustrating a portion of a display panel, according to an embodiment;

FIG. 20 is a schematic view for describing an arrangement of pixels of a display panel, according to an embodiment; and

FIG. 21 is a schematic perspective view illustrating an electronic device, according to an embodiment.

### DETAILED DESCRIPTION OF THE EMBODIMENTS

Reference will now be made in detail to embodiments, examples of which are illustrated in the accompanying drawings, wherein like reference numerals refer to like elements throughout. In this regard, embodiments may have different forms and should not be construed as being limited to the descriptions set forth herein. Accordingly, the embodiments are described below, by referring to the figures, to explain aspects of the description.

As used herein, the term “and/or” includes any and all combinations of one or more of the associated listed items.

Throughout the disclosure, the expression “at least one of a, b or c” indicates only a, only b, only c, both a and b, both a and c, both b and c, all of a, b, and c, or variations thereof.

As the disclosure allows for various changes and numerous embodiments, embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

While such terms as “first,” “second,” etc., may be used to describe various components, such components are not limited to the above terms. The above terms are used only to distinguish one component from another.

The singular forms “a,” “an,” and “the” as used herein are intended to include the plural forms as well unless the context clearly indicates differently.

It will be understood that the terms “including,” and “having,” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

In the specification, it will be understood that when a layer, a region, or a component is referred to as being “connected” to another layer, region, or component, it may be “directly connected” to the other layer, region, or component and/or may be “indirectly connected” to the other layer, region, or component with other layers, regions, or components disposed therebetween. For example, when a layer, a region, or a component is referred to as being “connected,” it may be directly connected, and/or may be indirectly electrically connected with intervening layers, regions, or components therebetween.

In the specification, an x-direction, a y-direction, and a z-direction are not limited to directions along three axes of the rectangular coordinate system, and may be interpreted in a broader sense. For example, the x-direction, the y-direction, and the z-direction may be perpendicular to one another, or may represent different directions that are not perpendicular to one another.

In the specification, when a component is seen in a “plan view”, it means that the component is seen from above (for example, the component is seen in a direction perpendicular to a top surface of a substrate), and when a component is seen in a “cross-sectional view”, it means that the component is cut vertically and seen from the side.

In the specification, when a first component “overlaps” a second component, it means that the first component is located over or under the second component so that at least a portion of the first component overlaps the second component in a plan view.

In the specification, the term “on” used in connection with an element state may refer to an active state of the element, and the term “off” may refer to an inactive state of the element. The term “on” used in connection with a signal received by an element may refer to a signal for activating the element, and the term “off” may refer to a signal for deactivating the element. The element may be activated by a high-level voltage or a low-level voltage. For example, a P-channel transistor (P-type transistor) is activated by a low-level voltage, and an N-channel transistor (N-type transistor) is activated by a high-level voltage. Accordingly, it should be understood that “on” voltages for the P-type transistor and the N-type transistor have opposite (high and low) voltage levels.

When an embodiment may be implemented differently, a specific process order may be different from the described order. For example, two consecutively described processes may be performed substantially at the same time or may be performed in an order opposite to the described order.

Sizes of components in the drawings may be exaggerated or reduced for convenience of explanation. For example, because sizes and thicknesses of components in the drawings are arbitrarily illustrated for convenience of explanation, the disclosure is not limited thereto.

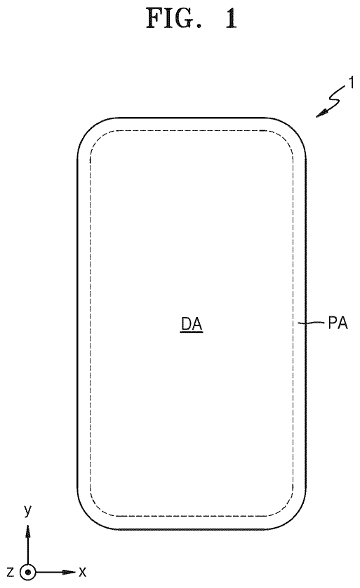

FIG. 1 is a schematic plan view schematically illustrating a display panel, according to an embodiment.

Referring to FIG. 1, a display panel 1 may include a display area DA where an image is displayed and a peripheral area PA outside the display area DA. The display panel 1 may provide a given image by using light emitted from pixels located (or disposed) in the display area DA. In an embodiment, each pixel may emit red light, green light, or blue light. In an embodiment, each pixel may emit red light, green light, blue light, or white light.

In a plan view, the display area DA may have a quadrangular shape. In an embodiment, the display area DA may have another polygonal shape, a circular shape, an elliptical shape, or an irregular shape. The display area DA may have a shape with round corners.

In an embodiment, the display panel 1 may have the display area DA in which a length in a first direction (x direction) is less than a length in a second direction (y direction). In an embodiment, the display panel 1 may have the display area DA in which a length in the first direction (x direction) is greater than a length in the second direction (y direction).

The peripheral area PA is located around the display area DA and may surround at least a part of the display area DA or may be adjacent to the display area DA. In an embodiment, the peripheral area PA may be a non-display area where pixels are not located. Various wirings for transmitting electric signals to be applied to the display area DA, circuits, and pads to which a printed circuit board or a driver integrated circuit (IC) chip is attached may be located in the peripheral area PA.

Although the display panel 1 according to an embodiment is an organic light-emitting display panel including an organic light-emitting diode, the display panel of the disclosure is not limited thereto. In an embodiment, the display panel 1 of the disclosure may include an inorganic light-emitting diode or may include a quantum dot light-emitting diode.

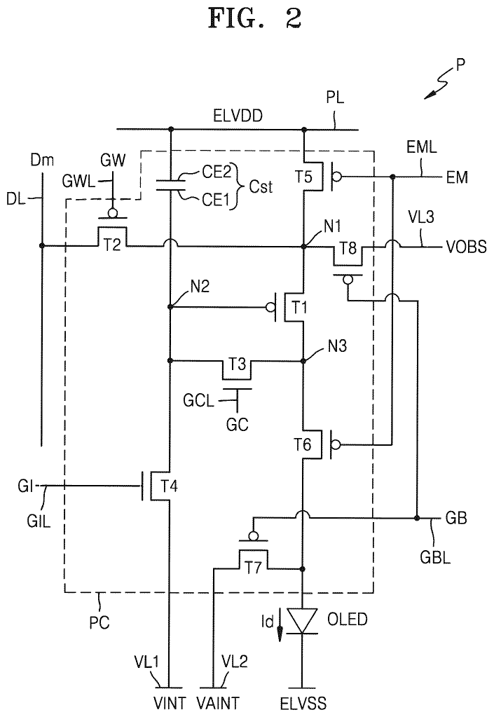

FIG. 2 is a schematic diagram of an equivalent circuit illustrating a pixel included in a display panel, according to an embodiment.

Referring to FIG. 2, a pixel circuit PC may include first to eighth transistors T1 to T8 and a storage capacitor Cst. According to a type (p-type or n-type) and/or an operating condition of a transistor, a first terminal of each of the first to eighth transistors T1 to T8 may be a source or a drain and a second terminal may be a terminal different from the first terminal. For example, in case that a first terminal is a source, a second terminal may be a drain. The first transistor T1 may be a driving transistor in which a magnitude of source-drain current is determined according to a gate-source voltage Vgs, and the second to eighth transistors T2 to T8 may be switching transistors that transmit signals.

The pixel circuit PC may be connected to a first gate line GWL that transmits a first gate signal GW, a second gate line GCL that transmits a second gate signal GC, a third gate line GIL that transmits a third gate signal GI, a fourth gate line GBL that transmits a fourth gate signal GB, an emission control line EML that transmits an emission control signal EM, a data line DL that transmits a data signal Dm, a driving voltage line PL that transmits a driving voltage ELVDD, a first initialization voltage line VL1 that transmits a first initialization voltage VINT, a second initialization voltage line VL2 that transmits a second initialization voltage VAINT, and a bias voltage line VL3 that transmits a bias voltage VOBS.

The first transistor T1 may include a gate connected to a second node N2, a first terminal connected to a first node N1, and a second terminal connected to a third node N3. The first transistor T1 receives the data signal Dm according to a switching operation of the second transistor T2 and supplies driving current Id to a light-emitting element.

The second transistor T2 may include a gate connected to the first gate line GWL, a first terminal connected to the data line DL, and a second terminal connected to the first node N1. The second transistor T2 may be turned on according to the first gate signal GW received through the first gate line GWL and may perform a switching operation of transmitting the data signal Dm transmitted through the data line DL to the first node N1.

The third transistor T3 may include a gate connected to the second gate line GCL, a first terminal connected to the second node N2, and a second terminal connected to the third node N3. The third transistor T3 may be turned on according to the second gate signal GC received through the second gate line GCL and may diode-connect the first transistor T1.

The fourth transistor T4 may include a gate connected to the third gate line GIL, a first terminal connected to the first initialization voltage line VL1, and a second terminal connected to the second node N2. The fourth transistor T4 may be turned on according to the third gate signal GI received through the third gate line GIL and may initialize a gate voltage of the first transistor T1 by transmitting the first initialization voltage VINT to the gate of the first transistor T1.

The fifth transistor T5 may include a gate connected to the emission control line EML, a first terminal connected to the driving voltage line PL, and a second terminal connected to the first node N1. The sixth transistor T6 may include a gate connected to the emission control line EML, a first terminal connected to the third node N3, and a second terminal connected to a pixel electrode of an organic light-emitting diode OLED. The fifth transistor T5 and the sixth transistor T6 may be simultaneously turned on by the emission control signal EM received through the emission control line EML so that the driving current Id flows through the organic light-emitting diode OLED.

The seventh transistor T7 may include a gate connected to the fourth gate line GBL, a first terminal connected to the second terminal of the sixth transistor T6 and the pixel electrode of the organic light-emitting diode OLED, and a second terminal connected to the second initialization voltage line VL2. The seventh transistor T7 may be turned on by the fourth gate signal GB received through the fourth gate line GBL and may initialize the pixel electrode of the organic light-emitting diode OLED by transmitting the second initialization voltage VAINT from the second initialization voltage line VL2 to the pixel electrode of the organic light-emitting diode OLED.

The eighth transistor T8 may include a gate connected to the fourth gate line GBL, a first terminal connected to the first node N1, and a second terminal connected to the bias voltage line VL3. The eighth transistor T8 may be turned on by the fourth gate signal GB received through the fourth gate line GBL and may transmit the bias voltage VOBS from the bias voltage line VL3 to the first node N1.

The storage capacitor Cst may include a first capacitor electrode CE1 connected to the second node N2 and a second capacitor electrode CE2 connected to the driving voltage line PL.

The organic light-emitting diode OLED may include the pixel electrode (for example, an anode) and a common electrode (for example, a cathode) facing the pixel electrode, and the common electrode may receive a common voltage ELVSS. The organic light-emitting diode OLED may receive the driving current Id from the first transistor T1 to emit light of a given color, thereby displaying an image.

Some of the first to eighth transistors T1 to T8 may be P-channel transistors, and the remaining some may be N-channel transistors. In an embodiment, the first transistor T1, the second transistor T2, and the fifth to eighth transistors T5 to T8 may be P-channel transistors, and the third transistor T3 and the fourth transistor T4 may be N-channel transistors. In other embodiments, all of the first to eighth transistors T1 to T8 may be N-channel transistors or P-channel transistors.

Although the pixel circuit PC may include the first to eighth transistors T1 to T8 and the storage capacitor Cst in FIG. 2, the disclosure is not limited thereto. Some transistors and capacitors may be omitted or added. For example, the pixel circuit PC may be designed in various ways. For example, the pixel circuit PC may include two transistors and one capacitor, may include four transistors and one capacitor, or may include seven transistors and one capacitor.

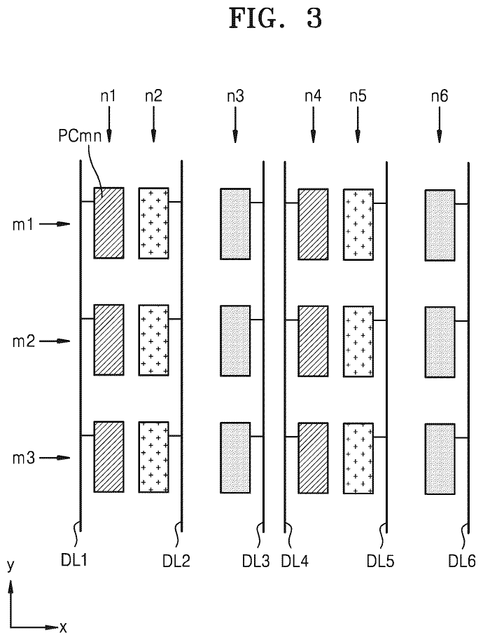

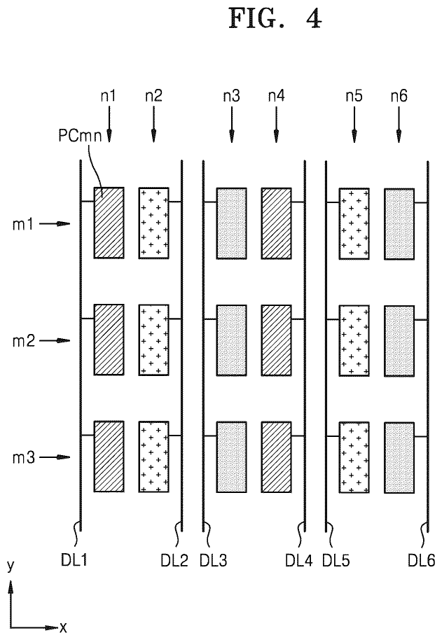

FIGS. 3 and 4 are views for describing a flip structure of a pixel circuit, according to an embodiment.

Referring to FIGS. 3 and 4, multiple pixel circuits PC may be arranged (or disposed) in a m×n matrix in the first direction (x direction) and the second direction (y direction. Here, m and n may each be a natural number equal to or greater than 1. The pixel circuits PC arranged in the first direction (x direction) form a pixel circuit row, and the pixel circuits PC arranged in the second direction (y direction) form a pixel circuit column. Although the pixel circuits PC are arranged in a 3×6 matrix with three rows m1, m2, m3 and six columns n1, n2, n3, n4, n5, n6 in FIGS. 3 and 4 for convenience of explanation, this is only an example, and the display panel 1 (see FIG. 1) may include a larger number of pixel circuits PC. A pixel circuit PCmn represents a pixel circuit PC located in the m-th row and n-th column.

The display panel 1 may include data lines DL (see FIG. 2). Each of the data lines DL may be arranged in each pixel circuit column. The pixel circuits PC arranged in the same pixel circuit column may be connected to the same data line. For example, pixel circuits PC11, PC21, and PC31 arranged in a first pixel circuit column n1 may be connected to a first data line DL1, pixel circuits PC12, PC22, and PC32 arranged in a second pixel circuit column n2 may be connected to a second data line DL2, pixel circuits PC13, PC23, and PC33 arranged in a third pixel circuit column n3 may be connected to a third data line DL3, pixel circuits PC14, PC24, and PC34 arranged in a fourth pixel circuit column n4 may be connected to a fourth data line DL4, pixel circuits PC15, PC25, and PC35 arranged in a fifth pixel circuit column n5 may be connected to a fifth data line DL5, and pixel circuits PC16, PC26, and PC36 arranged in a sixth pixel circuit column n6 may be connected to a sixth data line DL6.

The pixel circuits PC connected to the same data line may be pixel circuits of the pixels P (see FIG. 2) emitting light of the same color. For example, each of the pixel circuits the PC11, PC14, PC21, PC24, PC31, and PC34 connected to the first data line DL1 and the fourth data line DL4 may be connected to the organic light-emitting diode OLED (see FIG. 2) emitting red light, each of the pixel circuits PC12, PC15, PC22, PC25, PC32, and PC35 connected to the second data line DL2 and the fifth data line DL5 may be connected to the organic light-emitting diode OLED emitting green light, and each of the pixel circuits PC13, PC16, PC23, PC26, PC33, and PC36 connected to the third data line DL3 and the sixth data line DL6 may be connected to the organic light-emitting diode OLED emitting blue light.

The pixel circuits PC arranged in the same pixel circuit row may be connected to the same gate lines. The gate lines may transmit gate signals to the pixel circuits PC respectively connected thereto.

In an embodiment, as shown in FIG. 3, the pixel circuits PC11, PC21, and PC31 arranged in the first pixel circuit column n1 and the pixel circuits PC12, PC22, and PC32 arranged in the second pixel circuit column n2 from among three pixel circuit columns (for example, n1, n2, and n3) may have a flip structure. In case that one pixel circuit has a flip structure with another pixel circuit, two pixel circuits may be substantially symmetrical to each other with respect to an imaginary straight line passing through a boundary between the two pixel circuits and extending in the second direction (y direction). Accordingly, the first data line DL1 may be connected to the pixel circuits PC11, PC21, and PC31 on a left side (−x direction) of the pixel circuits PC11, PC21, and PC31 arranged in the first pixel circuit column n1, and the second data line DL2 may be connected to the pixel circuits PC12, PC22, and PC32 on a right side (+x direction) of the pixel circuits PC12, PC22, and PC32 arranged in the second pixel circuit column n2. The third data line DL3 may be connected to the pixel circuits PC13, PC23, and PC33 on a right side (+x direction) of the pixel circuits PC13, PC23, and PC33 arranged in the third pixel circuit column n3.

The pixel circuits PC and the data lines DL may be repeatedly arranged in units of three pixel circuit columns. For example, the pixel circuits PC14, PC24, and PC34 arranged in the fourth pixel circuit column n4 and the pixel circuits PC15, PC25, and PC35 arranged in the fifth pixel circuit column n5 may have a flip structure. The fourth data line DL4 may be connected to the pixel circuits PC14, PC24, and PC34 on a left side (−x direction) of the pixel circuits PC14, PC24, and PC34 arranged in the fourth pixel circuit column n4, and the fifth data line DL5 may be connected to the pixel circuits PC15, PC25, and PC35 on a right side (+x direction) of the pixel circuits PC15, PC25, and PC35 arranged in the fifth pixel circuit column n5. The sixth data line DL6 may be connected to the pixel circuits PC16, PC26, and PC36 on a right side (+x direction) of the pixel circuits PC16, PC26, and PC36 arranged in the sixth pixel circuit column n6.

In an embodiment, as shown in FIG. 4, pixel circuits arranged in an odd-numbered pixel circuit column may have a flip structure with pixel circuits arranged in an adjacent even-numbered pixel circuit column. For example, the pixel circuits PC11, PC21, and PC31 arranged in the first pixel circuit column n1 may have a flip structure with the pixel circuits PC12, PC22, and PC32 arranged in the second pixel circuit column n2, the pixel circuits PC13, PC23, and PC33 arranged in the third pixel circuit column n3 may have a flip structure with the pixel circuits PC14, PC24, and PC34 arranged in the fourth pixel circuit column n4, and the pixel circuits PC15, PC25, and PC35 arranged in the fifth pixel circuit column n5 may have a flip structure with the pixel circuits PC16, PC26, and PC36 arranged in the sixth pixel circuit column n6.

In an embodiment, each of the odd-numbered data lines DL1, DL3, and DL5 may be arranged on a left side (−x direction) of a pixel circuit column connected thereto, and each of the even-numbered data lines DL2, DL4, and DL6 may be arranged on a right side (+x direction) of a pixel circuit column connected thereto. In an embodiment, each of the odd-numbered data lines DL1, DL3, and DL5 may be arranged on a right side (+x direction) of a pixel circuit column connected thereto, and each of the even-numbered data lines DL2, DL4, and DL6 may be arranged on a left side (−x direction) of a pixel circuit column connected thereto.

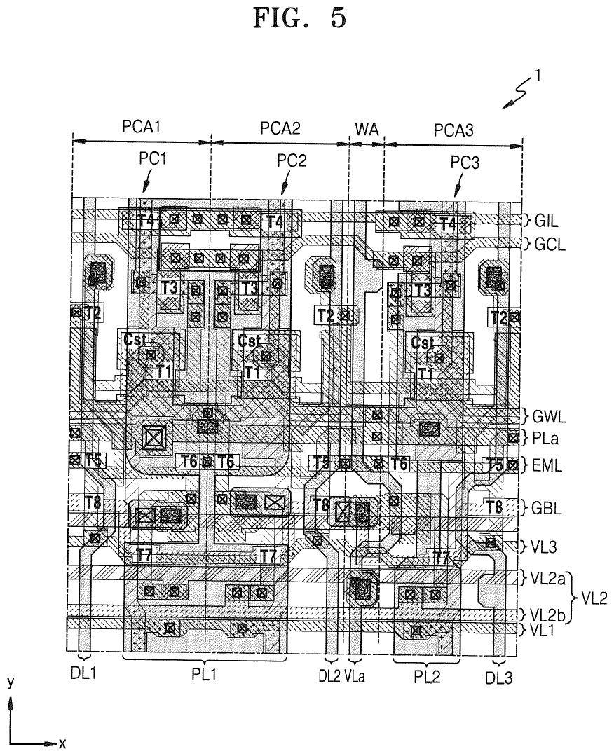

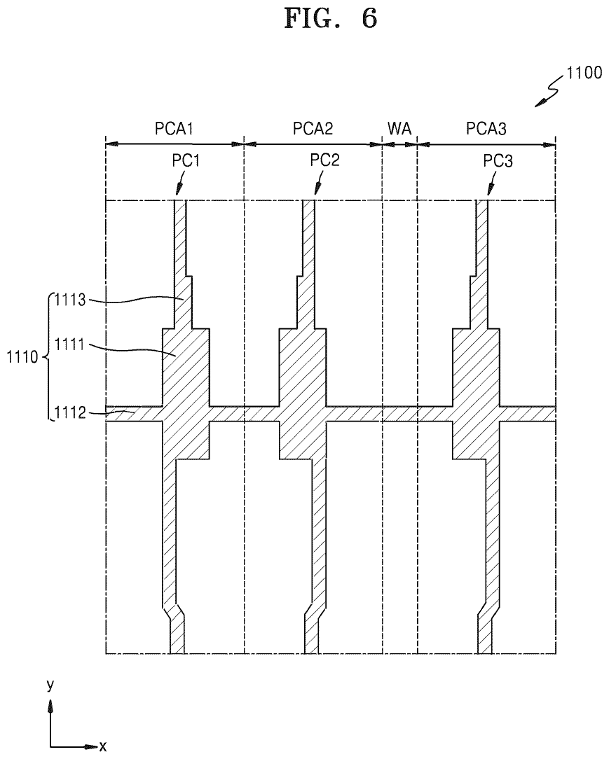

FIG. 5 is a schematic plan view illustrating a portion of a display panel, according to an embodiment. FIGS. 6 to 16 are schematic plan views each illustrating a portion of the display panel of FIG. 5 for each layer.

Referring to FIG. 5, the display panel 1 may include circuit areas (for example, first to third circuit areas PCA1, PCA2, and PCA3) where first to third pixel circuits PC1, PC2, and PC3 are located and a wiring area WA. The first pixel area PCA1, the second pixel circuit area PCA2, and the third pixel area PCA3 may be arranged side by side in the first direction (x direction). For example, the pixel circuit PC1, the second pixel circuit PC2, and the third pixel circuit PC3 may be pixel circuits arranged in the same pixel circuit row.

Each of the pixel circuit PC1, the second pixel circuit PC2, and the third pixel circuit PC3 may include the first to eighth transistors T1, T2, . . . , and T8 and the storage capacitor Cst. Each of the pixel circuit PC1, the second pixel circuit PC2, and the third pixel circuit PC3 may further include conductive patterns for connecting the first to eighth transistors T1, T2, . . . , and T8 and the storage capacitor Cst to gate lines, voltage lines, a data line, and a pixel electrode.

The pixel circuit PC1, the second pixel circuit PC2, and the third pixel circuit PC3 may include substantially the same or similar components unless otherwise described. Although components of the first pixel circuit PC1 are described for convenience of explanation, components corresponding to the components of the first pixel circuit PC1 may be included in the second and third pixel circuits PC2 and PC3.

The first pixel circuit PC1 and the second pixel circuit PC2 may have a flip structure. For example, the first pixel circuit PC1 and the second pixel circuit PC2 may be substantially symmetrical to each other with respect to an imaginary straight line extending in the second direction (y direction) along a boundary between the first pixel circuit PC1 and the second pixel circuit PC2. For example, in the first pixel circuit PC1, the second transistor T2 may be located on a left side (−x direction) with respect to the first transistor T1, and in the second pixel circuit PC2, the second transistor T2 may be located on a right side (+x direction) with respect to the first transistor T1. Components of the third pixel circuit PC3 may be located at positions substantially the same as or similar to those of the second pixel circuit PC2.

The first pixel circuit PC1, the second pixel circuit PC2, and the third pixel circuit PC3 may be connected to gate lines and voltage lines extending in the first direction (x direction). The gate lines may include the first gate line GWL, the second gate line GCL, the third gate line GIL, the fourth gate line GBL, and the emission control line EML. The voltage lines extending in the first direction (x direction) may include the first initialization voltage line VL1, the second initialization voltage line VL2, the bias voltage line VL3, and a horizontal driving voltage line PLa. The second initialization voltage line VL2 may include a 2-1 initialization voltage line VL2a and a 2-2 initialization voltage line VL2b. The 2-1 initialization voltage line VL2a may be connected to the first pixel circuit PC1, and the 2-2 initialization voltage line VL2b may be connected to the second pixel circuit PC2 and the third pixel circuit PC3.

The first pixel circuit PC1 may be connected to the first data line DL1 extending in the second direction (y direction), the second pixel circuit PC2 may be connected to the second data line DL2 extending in the second direction (y direction), and the third pixel circuit PC3 may be connected to the third data line DL3 extending in the second direction (y direction).

The first pixel circuit PC1 and the second pixel circuit PC2 may be connected to a first driving voltage line PL1 extending in the second direction (y direction). The third pixel circuit PC3 may be connected to a second driving voltage line PL2 extending in the second direction (y direction).

The wiring area WA may be located between the second pixel area PCA2 and the third pixel area PCA3. In the wiring area WA, an auxiliary voltage line VLa extending in the second direction (y direction) may be located. The auxiliary voltage line VLa may be connected to any one of the voltage lines extending in the first direction (x direction), for example, the first initialization voltage line VL1, the second initialization voltage line VL2, and the bias voltage line VL3. In this regard, the auxiliary voltage line VLa is connected to the 2-1 initialization voltage line VL2a in FIGS. 5 to 16. The auxiliary voltage line VLa may be connected to one of the voltage lines extending in the first direction (x direction) to form a mesh structure in the display area DA (see FIG. 1). The mesh structure may prevent a voltage drop of constant voltages such as the first initialization voltage VINT (see FIG. 2), the second initialization voltage VAINT (see FIG. 2), and the bias voltage VOBS (see FIG. 2) so that the display panel 1 displays a high-quality image.

A unit area including the first pixel area PCA1, the second pixel area PCA2, the wiring area WA, and the third pixel area PCA3 may be repeatedly arranged in the first direction (x direction) and the second direction (y direction).

A first conductive layer 1100 may be located on a substrate. The first conductive layer 1100 may include a conductive material such as molybdenum (Mo), aluminum (Al), copper (Cu), or titanium (Ti), and may have a single or multi-layer structure including the above material.

Referring to FIG. 6, the first conductive layer 1100 may include a first conductive pattern 1110. The first conductive pattern 1110 may include first body portions 1111, first horizontal connecting portions 1112 connecting the first body portions 1111 adjacent to each other in the first direction (x direction), and first vertical connecting portions 1113 connecting the first body portions 1111 adjacent to each other in the second direction (y direction). The first body portion 1111 may overlap a first channel region A1 of a first semiconductor layer 1200 in a plan view to prevent the first transistor T1 from being degraded due to external light.

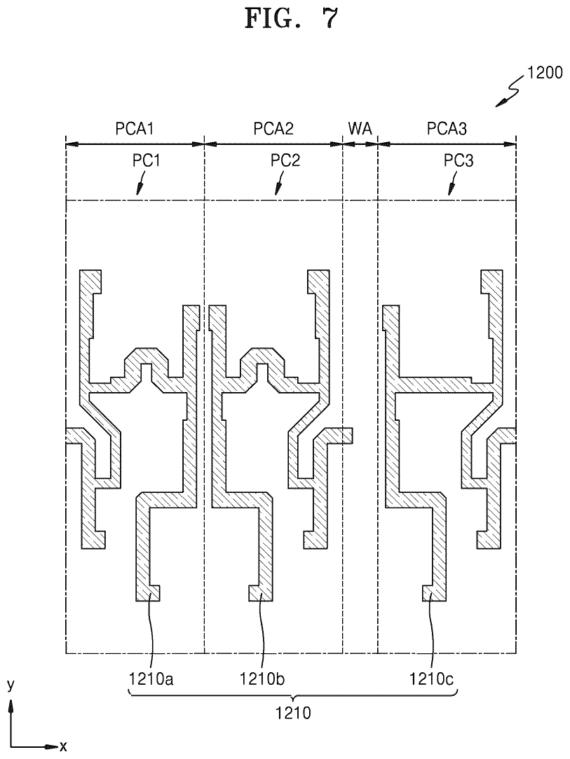

The first semiconductor layer 1200 may be located on the first conductive layer 1100. The first semiconductor layer 1200 may include a silicon-based semiconductor material, for example, amorphous silicon or polycrystalline silicon. Referring to FIG. 7, the first semiconductor layer 1200 may include a first semiconductor pattern 1210. For convenience of explanation, the first semiconductor pattern 1210 located in the first pixel area PCA1 may be referred to as a first semiconductor pattern 1210a, the first semiconductor pattern 1210 located in the second pixel area PCA2 may be referred to as a 1-2 semiconductor pattern 1210b, and the first semiconductor pattern 1210 located in the third pixel area PCA3 may be referred to as a 1-3 semiconductor pattern 1210c.

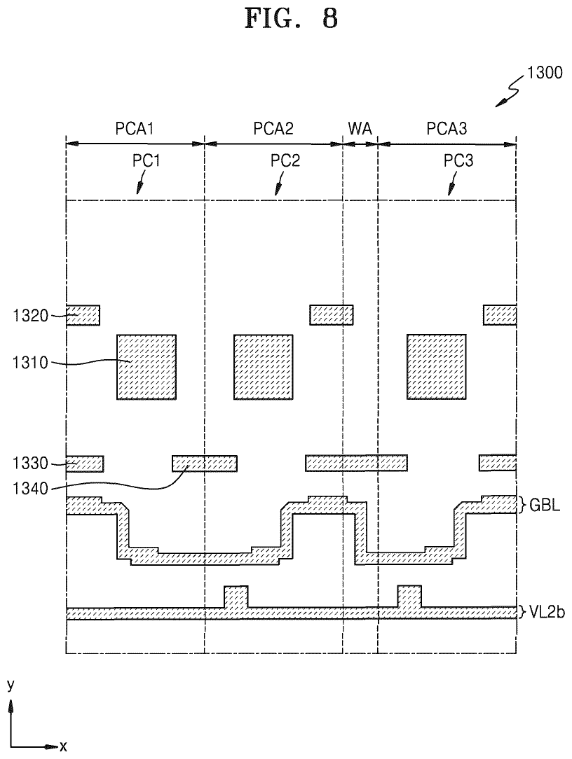

A second conductive layer 1300 may be located on the first semiconductor layer 1200. The first semiconductor layer 1200 may include a conductive material such as Mo, Al, Cu, or Ti, and may have a single or multi-layer structure including the above material. Referring to FIG. 8, the second conductive layer 1300 may include a second conductive pattern 1310, a third conductive pattern 1320, a fourth conductive pattern 1330, a fifth conductive pattern 1340, the fourth gate line GBL, and the 2-2 initialization voltage line VL2b.

Each of the second conductive pattern 1310, the third conductive pattern 1320, the fourth conductive pattern 1330, and the fifth conductive pattern 1340 may have an isolated shape (island type) in a plan view. The fourth gate line GBL and the 2-2 initialization voltage line VL2b may extend substantially in the first direction (x direction) and may pass through the first pixel area PCA1, the second pixel area PCA2, and the third pixel area PCA3. The fourth gate line GBL may transmit the fourth gate signal GB (see FIG. 5) to the pixel circuits PC1, PC2, and PC3 arranged in the same pixel circuit row.

In an embodiment, the second initialization voltage VAINT (see FIG. 2) may vary according to a pixel. For example, a 2-1 initialization voltage may be transmitted to the first pixel circuit PC1, and a 2-2 initialization voltage may be transmitted to the second pixel circuit PC2 and the third pixel circuit PC3. The 2-1 initialization voltage and the 2-2 initialization voltage may be different from each other. The 2-2 initialization voltage line VL2b may transmit the 2-1 initialization voltage to the second pixel circuit PC2 and the third pixel circuit PC3.

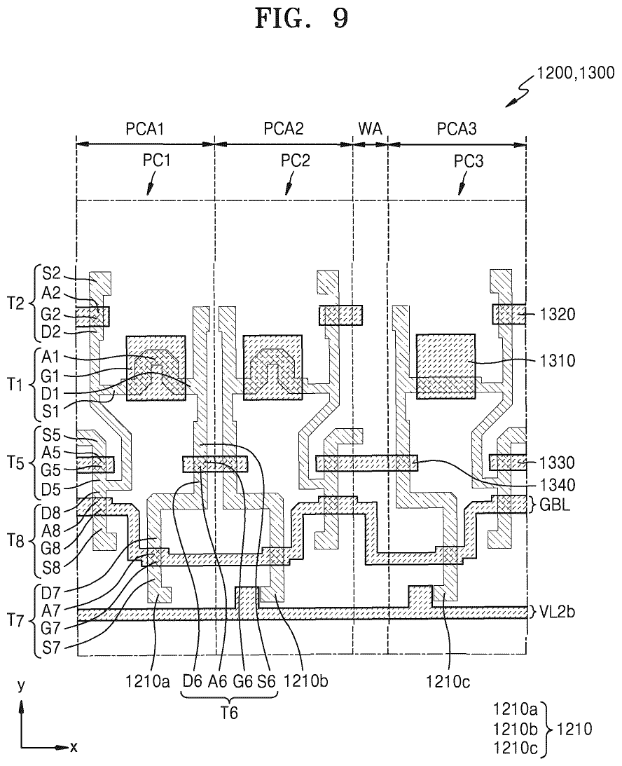

In FIG. 9, for convenience of explanation, the first semiconductor layer 1200 and the second conductive layer 1300 overlap each other. Referring to FIG. 9, each of the 1-1 semiconductor pattern 1210a, the 1-2 semiconductor pattern 1210b, and the 1-3 semiconductor pattern 1210c may include a first channel region A1 of the first transistor T1, a second channel region A2 of the second transistor T2, a fifth channel region A5 of the fifth transistor T5, a sixth channel region A6 of the sixth transistor T6, a seventh channel region A7 of the seventh transistor T7, and an eighth channel region A8 of the eighth transistor T8. Each of the 1-1 semiconductor pattern 1210a, the 1-2 semiconductor pattern 1210b, and the 1-3 semiconductor pattern 1210c may include first, second, fifth, sixth, and eighth source regions S1, S2, S5, S6 and S8 and first, second, fifth, sixth, and eighth drain regions D1, D2, D5, D6 and D8. A source region and a drain region may be located on both sides of each of the first, second, fifth, sixth, and eighth channel regions A1, A2, A5, A6, A7, and A8. The 1-1 semiconductor pattern 1210a may be integral with a first semiconductor pattern located on a left side (−x direction) of the first pixel area PCA1. The 1-3 semiconductor pattern 1210c may be integral with a first semiconductor pattern located on a right side (+x direction) of the third pixel circuit PC3. The 1-2 semiconductor pattern 1210b may be spaced apart from adjacent first semiconductor patterns 1210.

The first channel region A1 of the first transistor T1 may overlap the second conductive pattern 1310. In an embodiment, each of the first channel region A1 of the 1-1 semiconductor pattern 1210a and the first channel region A1 of the 1-2 semiconductor pattern 1210b may have a curved shape, and the first channel region A1 of the 1-3 semiconductor pattern 1210c may have a linear shape. The second conductive pattern 1310 may be a first gate electrode G1 of the first transistor T1. A source region S1 and a drain region D1 may be located on both sides of the first channel region A1 of the first transistor T1.

The second channel region A2 of the second transistor T2 may overlap the third conductive pattern 1320. The third conductive pattern 1320 may be a second gate electrode G2 of the second transistor T2. The first source region S1 may be disposed between the first channel region A1 and the second channel region A2 and may protrude beyond the first conductive pattern 1110 and the second conductive pattern 1310 in the first direction in a plan view, and.

The fifth channel region A5 of the fifth transistor T5 may overlap the fourth conductive pattern 1330. The fourth conductive pattern 1330 may be a fifth gate electrode G5 of the fifth transistor T5. The sixth channel region A6 of the sixth transistor T6 may overlap the fifth conductive pattern 1340. The fifth conductive pattern 1340 may be a sixth gate electrode G6 of the sixth transistor T6. The fourth conductive pattern 1330 of the second pixel circuit PC2 may be integral with the fifth conductive pattern 1340 of the third pixel circuit PC3.

The seventh channel region A7 of the seventh transistor T7 and the eighth channel region A8 of the eighth transistor T8 may overlap the fourth gate line GBL. A portion of the fourth gate line GBL overlapping the seventh channel region A7 may be a seventh gate electrode G7 of the seventh transistor T7, and a portion of the fourth gate line GBL overlapping the eighth channel region A8 may be an eighth gate electrode G8 of the eighth transistor T8.

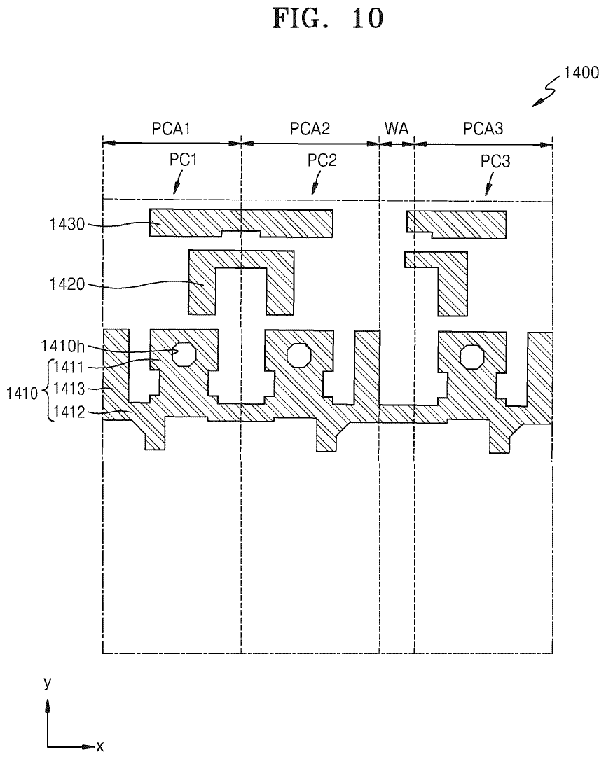

Referring to FIG. 10, a third conductive layer 1400 may be located on the second conductive layer 1300. The third conductive layer 1400 may include a conductive material such as molybdenum (Mo), aluminum (Al), copper (Cu), or titanium (Ti), and may have a single or multi-layer structure including the above material. The third conductive layer 1400 may include a sixth conductive pattern 1410, a seventh conductive pattern 1420, and an eighth conductive pattern 1430. Each of the seventh conductive pattern 1420 and the eighth conductive pattern 1430 may have an isolated shape in a plan view.

The sixth conductive pattern 1410 may include second body portions 1411, second horizontal connecting portions 1412 connecting the second body portions 1411 adjacent to each other in the first direction (x direction), and shielding portions 1413 protruding from the second horizontal connecting portions 1412 in the second direction (y direction).

The second body portion 1411 may overlap the second conductive pattern 1310 in a plan view to form the storage capacitor Cst. For example, the second conductive pattern 1310 may function as the first capacitor electrode CE1 (see FIG. 2) of the storage capacitor Cst, and the second body portion 1411 of the sixth conductive pattern 1410 may function as the second capacitor electrode CE2 (see FIG. 2) of the storage capacitor Cst. The second body portion 1411 may define a first hole 1410h through which a portion of the second conductive pattern 1310 is exposed.

In a plan view, the shielding portions 1413 may overlap the first data line DL1, the second data line DL2, and the third data line DL3 of a sixth conductive layer 1800. The shielding portions 1413 may be located between the first data line DL1 and the 1-1 semiconductor pattern 1210a, between the second data line DL2 and the 1-2 semiconductor pattern 1210b, and between the third data line DL3 and the 1-3 semiconductor pattern 1210c to reduce parasitic capacitance between the data line DL and the first semiconductor pattern 1210 overlapping the data line DL.

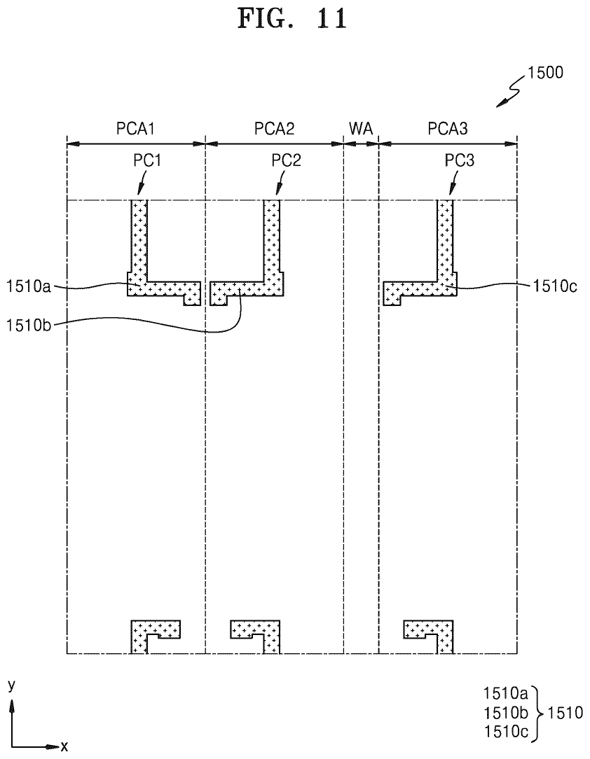

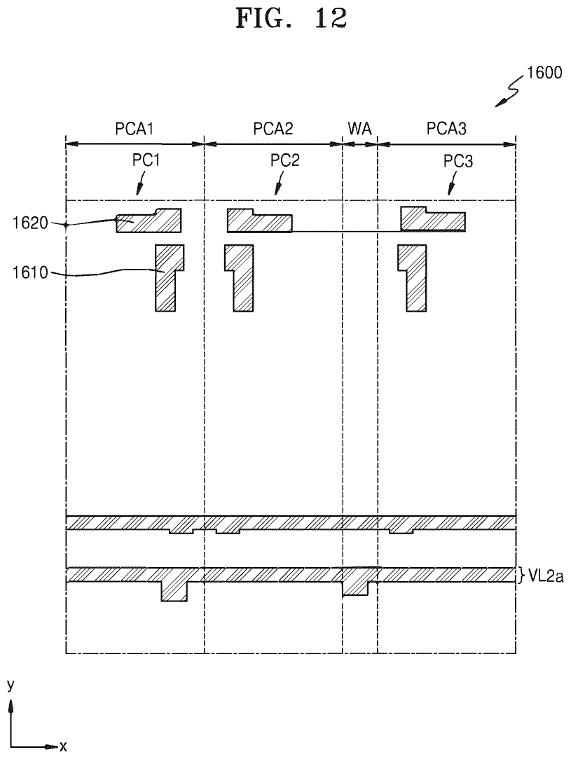

Referring to FIG. 11, a second semiconductor layer 1500 may be located on the third conductive layer 1400. The second semiconductor layer 1500 may include an oxide-based semiconductor material, for example, an oxide of at least one material selected from the group consisting of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In an embodiment, the second semiconductor layer 1500 may be In—Ga—Zn—O (IGZO) or In—Sn—Ga—Zn—O (ITGZO). The second semiconductor layer 1500 may include second semiconductor patterns 1510. The second semiconductor pattern 1510 located in the first pixel area PCA1 may be referred to as a 2-1 semiconductor pattern 1510a, the second semiconductor pattern 1510 located in the second pixel area PCA2 may be referred to as a 2-2 semiconductor pattern 1510b, and the second semiconductor pattern 1510 located in the third pixel area PCA3 may be referred to as a 2-3 semiconductor pattern 1510c. Referring to FIG. 12, a fourth conductive layer 1600 may be located on the second semiconductor layer 1500. The fourth conductive layer 1600 may include a conductive material such as molybdenum (Mo), aluminum (Al), copper (Cu), or titanium (Ti), and may have a single or multi-layer structure including the above material. The fourth conductive layer 1600 may include a ninth conductive pattern 1610, a tenth conductive pattern 1620, and the 2-1 initialization voltage line VL2a. Each of the ninth conductive pattern 1610 and the tenth conductive pattern 1620 may have an isolated shape in a plan view. The 2-1 initialization voltage line VL2a may extend in the first direction (x direction) and may pass through the first pixel area PCA1, the second pixel area PCA2, and the third pixel area PCA3. The 2-1 initialization voltage line VL2a may transmit a 2-1 initialization voltage to the first pixel circuit PC1.

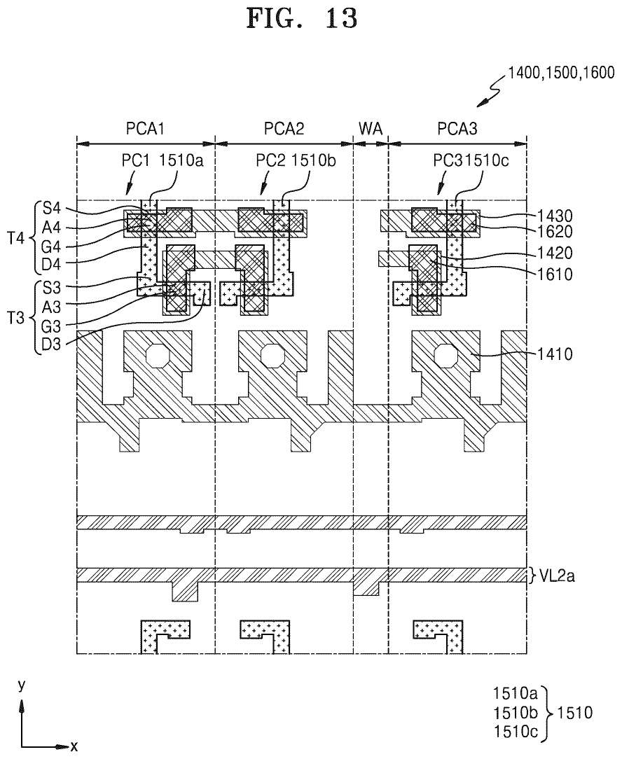

In FIG. 13, for convenience of explanation, the third conductive layer 1400, the second semiconductor layer 1500, and the fourth conductive layer 1600 overlap each other. Referring to FIG. 13, each of the 2-1 semiconductor pattern 1510a, the 2-2 semiconductor pattern 1510b, and a 2-3 semiconductor pattern 1510c may include a third channel region A3 of the third transistor T3 and a fourth channel region A4 of the fourth transistor T4. A source region and a drain region may be located on both sides of each of the third and fourth channel regions A3 and A4.

The third channel region A3 of the third transistor T3 may overlap the seventh conductive pattern 1420 and the ninth conductive pattern 1610. The seventh conductive pattern 1420 may be a lower gate electrode of the third transistor T3, and the ninth conductive pattern 1610 may be an upper gate electrode G3 of the third transistor T3.

The fourth channel region A4 of the fourth transistor T4 may overlap the eighth conductive pattern 1430 and the tenth conductive pattern 1620. The eighth conductive pattern 1430 may be a lower gate electrode of the fourth transistor T4, and the tenth conductive pattern 1620 may be an upper gate electrode G4 of the fourth transistor T4.

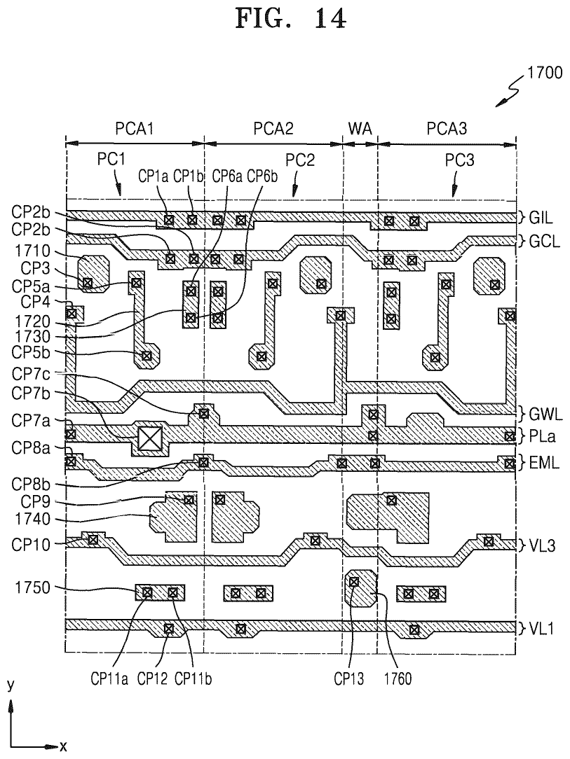

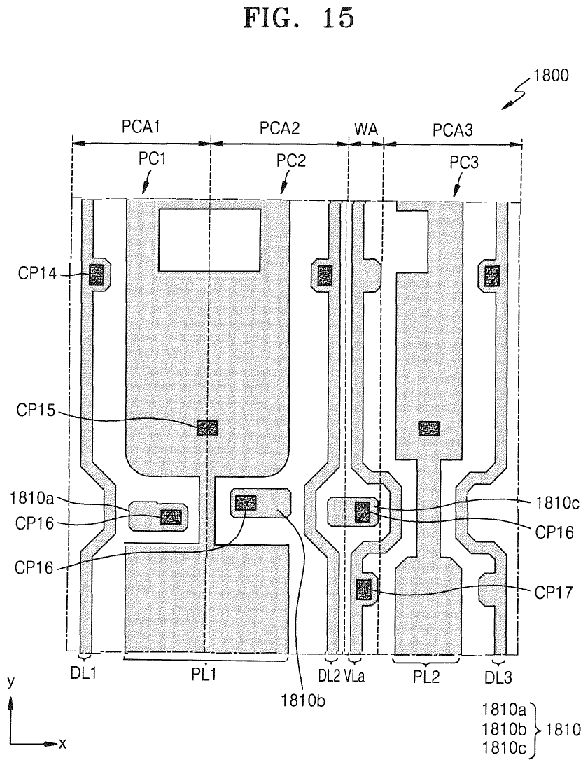

Referring to FIGS. 14 and 15 together, a fifth conductive layer 1700 may be located on the fourth conductive layer 1600, and the sixth conductive layer 1800 may be located on the fifth conductive layer 1700. Each of the fifth conductive layer 1700 and the sixth conductive layer 1800 may include a conductive material such as molybdenum (Mo), aluminum (Al), copper (Cu), or titanium (Ti), and may have a single or multi-layer structure including the above material. In an embodiment, each of the fifth conductive layer 1700 and the sixth conductive layer 1800 may have a multi-layer structure including Ti/Al/Ti.

The fifth conductive layer 1700 may include an 11^{th} conductive pattern 1710, a 12^{th} conductive pattern 1720, a 13^{th} conductive pattern 1730, a 14^{th} conductive pattern 1740, a 15^{th} conductive pattern 1750, a 16^{th} conductive pattern 1760, the first gate line GWL, the second gate line GCL, the third gate line GIL, the emission control line EML, the first initialization voltage line VL1, the bias voltage line VL3, and the horizontal driving voltage line PLa. The sixth conductive pattern 1800 may include a 17^{th} conductive pattern 1810, the first data line DL1, the second data line DL2, the third data line DL3, the first driving voltage line PL1, the second driving voltage line PL2, and the auxiliary voltage line VLa.

Each of the 11^{th} conductive pattern 1710, the 12^{th} conductive pattern 1720, the 13^{th} conductive pattern 1730, the 14^{th} conductive pattern 1740, the 15^{th} conductive pattern 1750, the 16^{th} conductive pattern 1760, and the 17^{th} conductive pattern 1810 may have an isolated shape in a plan view.

The 11th conductive pattern 1710 may be a connection electrode that connects the data line DL (see FIG. 2) to a source region S2 of the second transistor T2. The 11th conductive pattern 1710 of the first pixel circuit PC1 may be connected to the 11 semiconductor pattern 1210a through a third contact hole CP3, and may be connected to the first data line DL1 through a 14th contact hole CP14. The 11th conductive pattern 1710 of the second pixel circuit PC2 may be connected to the 1-2 semiconductor pattern 1210b through the third contact hole CP3, and may be connected to the second data line DL2 through the 14th contact hole CP14. The 11th conductive pattern 1710 of the third pixel circuit PC3 may be connected to the 1-3 semiconductor pattern 1210c through the third contact hole CP3, and may be connected to the third data line DL3 through the 14th contact hole CP14.

The 12th conductive pattern 1720 may be a connection electrode that connects the first gate electrode G1 of the first transistor T1, a source region S3 of the third transistor T3, and a drain region D4 of the fourth transistor T4. The 12th conductive pattern 1720 may be connected to the second semiconductor pattern 1510 through a 5-1 contact hole CP5a, and may be connected to the second conductive pattern 1310 through the first hole 1410h and a 5-2 contact hole CP5b.

The 13^{th} conductive pattern 1730 may be a connection electrode that connects the drain region D1 of the first transistor T1 to a drain region D3 of the third transistor T3. The 13^{th} conductive pattern 1730 may be connected to the second semiconductor pattern 1510 through a 6-1 contact hole CP6a, and may be connected to the first semiconductor pattern 1210 through a 6-2 contact hole CP6b.

The 14th conductive pattern 1740 and the 17th conductive pattern 1810 may be connection electrodes that connect a drain region D6 of the sixth transistor T6, a drain region D7 of the seventh transistor T7, and a pixel electrode 210. For convenience of explanation, the 17th conductive pattern 1810 located in the first pixel area PCA1 may be referred to as a 17-2 conductive pattern 1810a, the 17th conductive pattern 1810 located in the second pixel area PCA2 may be referred to as a 17-2 conductive pattern 1810b, and the 17th conductive pattern 1810 located in the third pixel area PCA3 may be referred to as a 17-3 conductive pattern 1810c.

The 14^{th} conductive pattern 1740 of the first pixel circuit PC1 may be connected to the 1-1 semiconductor pattern 1210a through a ninth contact hole CP9, and may be connected to the 17-1 conductive pattern 1810a through a 16th contact hole CP16. The 14th conductive pattern 1740 of the second pixel circuit PC2 may be connected to the 1-2 semiconductor pattern 1210b through the ninth contact hole CP9, and may be connected to the 17-2 conductive pattern 1810b through the 16th contact hole CP16. The 14th conductive pattern 1740 of the third pixel circuit PC3 may be connected to the 1-3 semiconductor pattern 1210c through the ninth contact hole CP9, and may be connected to the 17-3 conductive pattern 1810c through the 16th contact hole CP16. The 17-1 conductive pattern 1810a may be connected to a first pixel electrode 210a through an 18th contact hole CP18, may be connected to a second pixel electrode 210b through the 18th contact hole CP18, and may be connected to a third pixel electrode 210c through the 18th contact hole CP18.

The 15th conductive pattern 1750 may be a connection electrode that connects a source region S7 of the seventh transistor T7 to the 2-1 initialization voltage line VL2a or the 2-2 initialization voltage line VL2b. The 15th conductive pattern 1750 of the first pixel circuit PC1 may be connected to the 1-1 semiconductor pattern 1210a through an 11-1 contact hole CP11a, and may be connected to the 2-1 initialization voltage line VL2a through an 11-2 contact hole CP11b. The 15th conductive pattern 1750 of the second pixel circuit PC2 may be connected to the 1-2 semiconductor pattern 1210b through the 11-1 contact hole CP11a, and may be connected to the 2-2 initialization voltage line VL2b through the 11-2 contact hole CP11b. The 15th conductive pattern 1750 of the third pixel circuit PC3 may be connected to the 1-3 semiconductor pattern 1210c through the 11-1 contact hole CP11a, and may be connected to the 2-2 initialization voltage line VL2b through the 11-2 contact hole CP11b.

The 16th conductive pattern 1760 may be located in the wiring area WA, and may be a connection electrode that connects the auxiliary voltage line VLa to any one of the first initialization voltage line VL1, the second initialization voltage line VL2, and the bias voltage line VL3. Referring to FIG. 14, the 16th conductive pattern 1760 may be connected to the 2-1 initialization voltage line VL2a through a 13th contact hole CP13, and may be connected to the auxiliary voltage line VLa through a 17th contact hole CP17.

The first gate line GWL, the second gate line GCL, the third gate line GIL, the emission control line EML, the first initialization voltage line VL1, the bias voltage line VL3, and the horizontal driving voltage line PLa may extend in the first direction (x direction) and may pass through the first pixel area PCA1, the second pixel area PCA2, and the third pixel area PCA3.

The first gate line GWL may be connected to the third conductive pattern 1320 through a fourth contact hole CP4. The first gate line GWL may transmit the first gate signal GW (see FIG. 2) to the second gate electrode G2 of the second transistor T2.

The second gate line GCL may be connected to the ninth conductive pattern 1610 through a 2-1 contact hole CP2a, and may be connected to the seventh conductive pattern 1420 through a 2-2 contact hole CP2b. The second gate line GCL may transmit the second gate signal GC (see FIG. 2) to the upper gate electrode G3 and the lower gate electrode of the third transistor T3.

The third gate line GIL may be connected to the tenth conductive pattern 1620 through a 1-1 contact hole CP1a, and may be connected to the eighth conductive pattern 1430 through a 1-2 contact hole CP1b. The third gate line GIL may transmit the third gate signal GI (see FIG. 2) to the upper gate electrode G4 and the lower gate electrode of the fourth transistor T4.

The emission control line EML may be connected to the fourth conductive pattern 1330 through an 8-1 contact hole CP8a, and may be connected to the fifth conductive pattern 1340 through an 8-2 contact hole CP8b. The emission control line EML may transmit the emission control signal EM (see FIG. 2) to the fifth gate electrode G5 of the fifth transistor T5 and the sixth gate electrode G6 of the sixth transistor T6.

The first initialization voltage line VL1 may be connected to the second semiconductor pattern 1510 through a 12th contact hole CP12. The first initialization voltage line VL1 may transmit the first initialization voltage VINT (see FIG. 2) to a source region S4 of the fourth transistor T4.

The bias voltage line VL3 may be connected to the first semiconductor pattern 1210 through a tenth contact hole CP10. The bias voltage line VL3 may transmit the bias voltage VOBS (see FIG. 2) to a source region S8 of the eighth transistor T8.

The horizontal driving voltage line PLa may be connected to the first semiconductor pattern 1210 through a 7-1 contact hole CP7a, may be connected to the first conductive pattern 1110 through a 7-2 contact hole CP7b, and may be connected to the sixth conductive pattern 1410 through a 7-3 contact hole CP7c. The 7-1 contact hole CP7a may be located in the first circuit area PCA1, and the 7-2 contact holes CP7b may be located at a boundary between the first circuit area PCA1 and the second pixel area PCA2 and a boundary between the second pixel area PCA2 and the third pixel area PCA3.

The horizontal driving voltage line PLa may be connected to the first driving voltage line PL1 through a 15^{th} contact hole CP15 located between the first pixel area PCA1 and the second pixel area PCA2, and may be connected to the second driving voltage line PL2 through the 15th contact hole CP15 located in the third pixel area PCA3. The horizontal driving voltage line PLa may be connected to the first driving voltage line PL1 and the second driving voltage line PL2 to form a mesh structure in the display area DA (see FIG. 1). The horizontal driving voltage line PLa may transmit the driving voltage ELVDD (see FIG. 2) to the second capacitor electrode CE2 of the storage capacitor Cst and a source region S5 of the fifth transistor T5.

Each of the first data line DL1, the second data line DL2, and the third data line DL3 may extend in the second direction (y direction). The first data line DL1 may be located on a left side (−x direction) of the first pixel circuit PC1, and the second data line DL2 may be located on a right side (+x direction) of the second pixel circuit PC2. The third data line DL3 may be located on a right side (+x direction) of the third pixel circuit PC3.

The first transistor T1 of the first pixel circuit PC1 and the first transistor T1 of the second pixel circuit PC2 may be located between the first data line DL1 and the second data line DL2. The third transistor T3 of the third pixel circuit PC3 may be located between the second data line DL2 and the third data line DL3.

Each of the first driving voltage line PL1 and the second driving voltage line PL2 may extend in the second direction (y direction). The first driving voltage line PL1 may be located between the first data line DL1 and the second data line DL2, and the second driving voltage line PL2 may be located between the second data line DL2 and the third data line DL3.

The first driving voltage line PL1 may overlap the first transistor T1 of the first pixel circuit PC1 and the first transistor T1 of the second pixel circuit PC2 to shield the first transistor T1 of the first pixel circuit PC1 and the first transistor T1 of the second pixel circuit PC2 from the electrical influence of components located over the first driving voltage line PL1. The first driving voltage line PL1 may overlap the 13^{th} conductive pattern 1730 of the first pixel circuit PC1 and the 13^{th} conductive pattern 1730 of the second pixel circuit PC2. The first pixel circuit PC1 and the second pixel circuit PC2 may share one first driving voltage line PL1 to reduce the total area of pixel circuits.

The second driving voltage line PL2 may overlap the first transistor T1 of the third pixel circuit PC3 to shield the first transistor T1 of the third pixel circuit PC3 from the electrical influence of components located over the second driving voltage line PL2.

The auxiliary voltage line VLa may be located between the second data line DL2 and the second driving voltage line PL2. The auxiliary voltage line VLa may be symmetrical to the third data line DL3 with respect to an imaginary straight line passing through the center of the third pixel electrode 210c. Accordingly, a third organic light-emitting diode including the third pixel electrode 210c may have the same luminance when viewed from the left (−x direction) and the right (+x direction).

The auxiliary voltage line VLa may be located between the second data line DL2 and the first transistor T1 of the third pixel circuit PC3. The 13^{th} conductive pattern 1730 of the first pixel circuit PC1 and the 13th conductive pattern 1730 of the second pixel circuit PC2 may be located close to a boundary between the first pixel area PCA1 and the second pixel area PCA2 and may be sufficiently spaced apart from the first data line DL1 and the second data line DL2 in the first direction (x direction). On the other hand, the 13th conductive pattern 1730 of the third pixel circuit PC3 may be located relatively adjacent to the second data line DL2. The auxiliary voltage line VLa may be located between the 13th conductive pattern 1730 of the third pixel circuit PC3 and the second data line DL2 to reduce parasitic capacitance between the 13th conductive pattern 1730 and the second data line DL2.

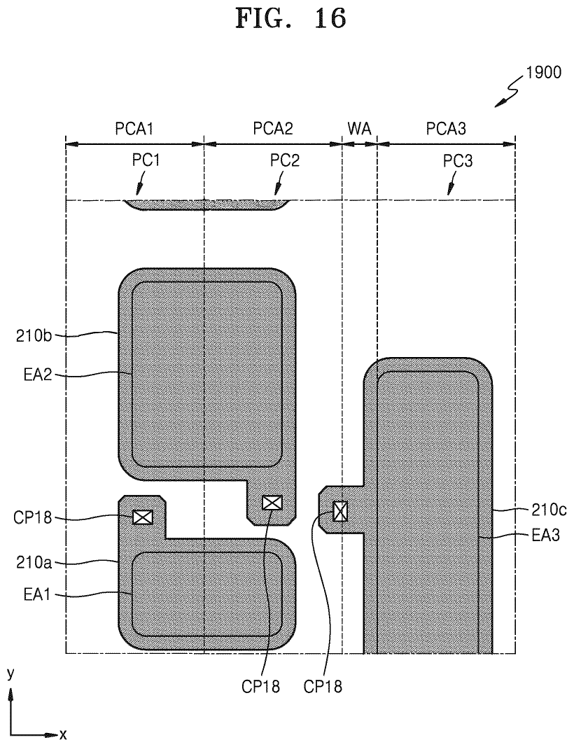

Referring to FIG. 16, a seventh conductive layer 1900 may be located on the sixth conductive layer 1800. The seventh conductive layer 1900 may include the first pixel electrode 210a, the second pixel electrode 210b, and the third pixel electrode 210c. The first pixel electrode 210a, the second pixel electrode 210b, and the third pixel electrode 210c may be arranged in a stripe shape. For example, the first pixel electrode 210a and the second pixel electrode 210b may be spaced apart from each other in the second direction (y direction), and the third pixel electrode 210c may be spaced apart from the first pixel electrode 210a and the second pixel electrode 210b in the first direction (x direction). A first emission area EA1 where red light is emitted may be defined in the first pixel electrode 210a, a second emission area EA2 where green light is emitted may be defined in the second pixel electrode 210b, and a third emission area EA3 where blue light is emitted may be defined in the third pixel electrode 210c. Each of the first pixel electrode 210a, the second pixel electrode 210b, and the third pixel electrode 210c may have a substantially quadrangular shape in a plan view. However, the disclosure is not limited thereto. The first pixel electrode 210a, the second pixel electrode 210b, and the third pixel electrode 210c may be arranged in any of various shapes such as a PENTILE™ shape or a mosaic shape, and each may have any of various shapes such as another polygonal shape, a circular shape, or an elliptical shape in a plan view.

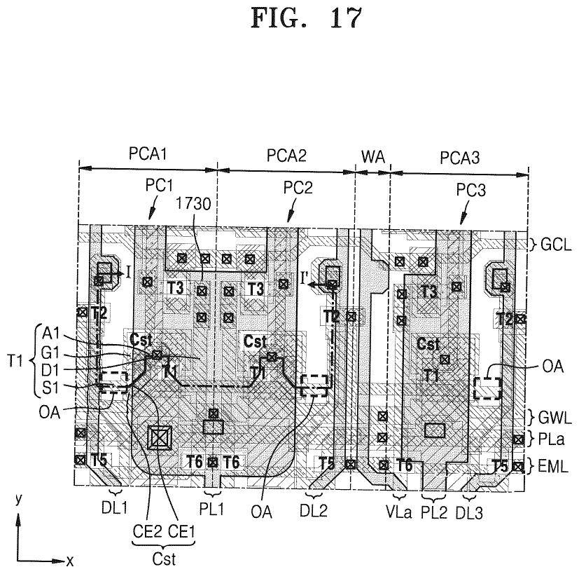

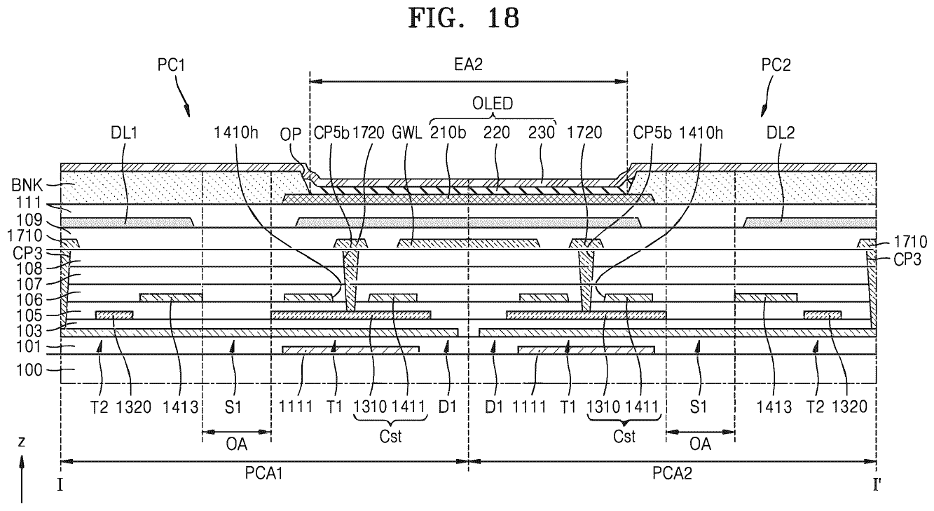

FIG. 17 is a schematic plan view illustrating a portion of a display panel, according to an embodiment. FIG. 18 is a schematic cross-sectional view taken along line I-I′ of the display panel of FIG. 17.

Referring to FIGS. 17 and 18 together, the display panel 1 (see FIG. 1) may include a substrate 100. The substrate 100 may include glass, a metal, or a polymer resin. The substrate 100 may be flexible or bendable. The substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. In an embodiment, the substrate 100 may have a multi-layer structure including two layers formed of a polymer resin and a barrier layer formed of an inorganic material (for example, silicon nitride, silicon oxide, or silicon oxynitride) and located between the two layers, and various modifications may be made.

The first pixel circuit PC1, the second pixel circuit PC2, and the third pixel circuit PC3 may be located on the substrate 100. The first pixel circuit PC1 and the second pixel circuit PC2 may be symmetrical to each other with respect to an imaginary straight line extending in the second direction (y direction) along a boundary between the first pixel area PCA1 and the second pixel area PCA2. Hereinafter, corresponding components symmetrical to each other will be described based on the first pixel circuit PC1.

The first conductive layer 1100 (see FIG. 6) may be located on the substrate 100. The first conductive layer 1100 may include the first conductive pattern 1110 (see FIG. 6). The first body portion 1111 of the first conductive pattern 1110 may overlap the first channel region A1 (see FIG. 7) of the first transistor T1.

A first insulating layer 101 may be located on the first conductive layer 1100, and the first semiconductor layer 1200 (see FIG. 7) may be located on the first insulating layer 101. The first semiconductor layer 1200 may include the first semiconductor pattern 1210. The first semiconductor pattern 1210 may include the first channel region A1 of the first transistor T1 and the second channel region A2 of the second transistor T2. The source region S1 of the first transistor T1 may be located between the first channel region A1 of the first transistor T1 and the second channel region A2 of the second transistor T2. The drain region D1 of the first transistor T1 may face the source region S1 of the first transistor T1 with the first channel region A1 therebetween.

A second insulating layer 103 may be located on the first semiconductor layer 1200, and the second conductive layer 1300 (see FIG. 8) may be located on the second insulating layer 103. The second conductive layer 1300 may include the second conductive pattern 1310 and the third conductive pattern 1320. The second conductive pattern 1310 may overlap the first body portion 1111 and the first channel region A1 of the first transistor T1. The second conductive pattern 1310 may be the first gate electrode G1 (see FIG. 9) of the first transistor T1. The third conductive pattern 1320 may overlap the second channel region A2 of the second transistor T2. The third conductive pattern 1320 may be the second gate electrode G2 (see FIG. 9) of the second transistor T2.

A third insulating layer 105 may be located on the second conductive layer 1300, and the third conductive layer 1400 (see FIG. 10) may be located on the third insulating layer 105. The third conductive layer 1400 may include the sixth conductive pattern 1410 (see FIG. 10). The sixth conductive pattern 1410 may include the second body portion 1411, and the second horizontal connecting portion 1412 (see FIG. 10) connecting the second body portions 1411 adjacent to each other in the first direction (x direction).

The second body portion 1411 may overlap the second conductive pattern 1310 to form the storage capacitor Cst. For example, the second conductive pattern 1310 may be the first capacitor electrode CE1 of the storage capacitor Cst, and the second body portion 1411 may be the second capacitor electrode CE2 of the storage capacitor Cst. The second body portion 1411 may define the first hole 1410h overlapping the second conductive pattern 1310 in a plan view.

As shown in FIG. 17, in a plan view, the source region S1 of the first transistor T1 may protrude from the first body portion 1111 of the first conductive pattern 1110, the second conductive pattern 1310, and the second body portion 1411 of the sixth conductive pattern 1410 in the first direction (x direction). In other words, the first conductive pattern, the second conductive pattern 1310, and the sixth conductive pattern 1410 may define an opening portion OA through which the source region S1 of the first transistor T1 is exposed so as not to overlap the source region S1 of the first transistor T1.

The shielding portions 1413 may extend in the second direction (y direction) to overlap the first data line DL1, the second data line DL2, and the third data line DL3 in a plan view. The shielding portions 1413 may shield a portion of the first semiconductor pattern 1210 (for example, the drain region of the second transistor T2) to reduce parasitic capacitance between the first data line DL1, the second data line DL2, and the third data line DL3, and the first semiconductor pattern 1210.

A fourth insulating layer 106, a fifth insulating layer 107, and a sixth insulating layer 108 may be sequentially stacked on the third conductive layer 1400. Although not shown in FIG. 18, the second semiconductor layer 1500 (see FIG. 11) may be located between the fourth insulating layer 106 and the fifth insulating layer 107, and the fourth conductive layer 1600 (see FIG. 12) may be located between the fifth insulating layer 107 and the sixth insulating layer 108.

The fifth conductive layer 1700 (see FIG. 14) may be located on the sixth insulating layer 108. The fifth conductive layer 1700 may include the 11^{th} conductive pattern 1710, the 12th conductive pattern 1720, and the first gate line GWL. The 11th conductive pattern 1710 may be connected to the first semiconductor pattern 1210 through the third contact hole CP3. The 11th conductive pattern 1710 of the first pixel area PCA1 may connect the first data line DL1 to the second transistor T2 of the first pixel circuit PC1, the 11th conductive pattern 1710 of the second pixel area PCA2 may connect the second data line DL2 to the second transistor T2 of the second pixel circuit PC2, and the 11th conductive pattern 1710 of the third pixel area PCA3 may connect the third data line DL3 to the third transistor T3 of the third pixel circuit PC3. The 12th conductive pattern 1720 may be connected to the second conductive pattern 1310 through the first hole 1410h and the 5-2 contact hole CP5b.

A seventh insulating layer 109 may be located on the fifth conductive layer 1700, and the sixth conductive layer 1800 (see FIG. 15) may be located on the seventh insulating layer 109. The sixth conductive layer 1800 may include the first data line DL1, the second data line DL2, the third data line DL3, the first driving voltage line PL1, the second driving voltage line PL2, and the auxiliary voltage line VLa.

The first transistor T1 of the first pixel circuit PC1 and the first transistor T1 of the second pixel circuit PC2 may be located between the first data line DL1 and the second data line DL2. The third transistor T3 of the third pixel circuit PC3 may be located between the second data line DL2 and the third data line DL3.

As shown in FIG. 17, the first driving voltage line PL1 may overlap the first transistor T1 of the first pixel circuit PC1 and the first transistor T1 of the second pixel circuit PC2. The first pixel circuit PC1 and the second pixel circuit PC2 may share one first driving voltage line PL1 to reduce the total area of pixel circuits. The second driving voltage line PL2 may overlap the first transistor T1 of the third pixel circuit PC3.

The auxiliary voltage line VLa may be located between the second data line DL2 and the second driving voltage line PL2. The auxiliary voltage line VLa may be located between the second data line DL2 and the first transistor T1 of the third pixel circuit PC3. The auxiliary voltage line VLa may reduce or prevent a change in luminance of an organic light-emitting diode connected to the third pixel circuit PC3 due to a data signal applied to the second data line DL2.

An eighth insulating layer 111 may be located on the sixth conductive layer 1800, and a second organic light-emitting diode OLED2 may be located on the eighth insulating layer 111. The second organic light-emitting diode OLED2 may include the second pixel electrode 210b, an emission layer 220, and a counter electrode 230. The second organic light-emitting diode OLED2 may be connected to the second pixel circuit PC2. Each of a first organic light-emitting diode connected to the first pixel circuit PC1 and a third organic light-emitting diode connected to the third pixel circuit PC3 may have a structure similar to that of the second organic light-emitting diode OLED2. Hereinafter, the second organic light-emitting diode OLED2 will be described.

The second pixel electrode 210b may be a (semi-) transmissive electrode or a reflective electrode. In an embodiment, the second pixel electrode 210b may include a reflective layer formed of silver (Ag), magnesium (Mg), aluminum (Al), platinum (Pt), palladium (Pd), gold (Au), nickel (Ni), neodymium (Nd), iridium (Ir), chromium (Cr), or a compound thereof, and a transparent or semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In an embodiment, the second pixel electrode 210b may include ITO/Ag/ITO.

A bank layer BNK may be located on the eighth insulating layer 111 to cover an edge of the second pixel electrode 210b. The bank layer BNK may define a pixel opening OP through which a central portion of the second pixel electrode 210b is exposed. The second emission area EA2 of the second organic light-emitting diode OLED2 may be defined by the pixel opening OP of the bank layer BNK.

The bank layer BNK may increase a distance between an edge of the second pixel electrode 210b and the counter electrode 230 to prevent an arc or the like from occurring at the edge of the second pixel electrode 210b. The bank layer BNK may include at least one organic material selected from the group consisting of polyimide, polyamide, acrylic resin, benzocyclobutene, and phenolic resin.

The emission layer 220 may be located on the second pixel electrode 210b. The emission layer 220 may include a high molecular weight organic material or a low molecular weight organic material that emits light of a given color. The emission layer 220 may further include a metal-containing compound such as an organo-metallic compound or an inorganic material such as quantum dots. In an embodiment, the emission layer 220 may be patterned to correspond to the second pixel electrode 210b.

A first functional layer may be located between the emission layer 220 and the second pixel electrode 210b, and a second functional layer may be located between the emission layer 220 and the counter electrode 230. The first functional layer may be a hole transport layer. By way of example, the first functional layer may include a hole injection layer and a hole transport layer. The second functional layer may include an electron transport layer and/or an electron injection layer. The first functional layer and the second functional layer may be integral to correspond to organic light-emitting diodes. The first functional layer or the second functional layer may be omitted.

In an embodiment, the second organic light-emitting diode OLED2 may be a tandem light-emitting element including two or more light-emitting units and a charge generation layer. The second organic light-emitting diode OLED2 may have a structure in which light-emitting units are stacked, to improve color purity and luminous efficiency.

The counter electrode 230 may be located on the emission layer 220. The counter electrode 230 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), indium tin oxide (ITO), indium zinc oxide (IZO), or any combination thereof. The counter electrode 230 may be a transmissive electrode, a semi-transmissive electrode, or a reflective electrode. The counter electrode 230 may be integral to correspond to organic light-emitting diodes.

The first to sixth conductive layers 1100, 1300, 1400, 1600, 1700, and 1800 and the second semiconductor layer 1500 described with reference to FIGS. 6 to 15 may not overlap the opening portions OA. Accordingly, the source region S1 of the first transistor T1 may be exposed to internal light reflected from a lower portion of the counter electrode 230, and a threshold voltage of the first transistor T1 and a driving (DR) range may be shifted. Accordingly, in case that a white grayscale block pattern and a black grayscale block pattern are simultaneously displayed for a given period of time and a gray grayscale is displayed on the entire display area DA (see FIG. 2), an afterimage phenomenon in which a luminance difference occurs between an area where the white grayscale block pattern is displayed and an area where the black grayscale block pattern is displayed may be reduced. Accordingly, the display panel 1 may display a high-quality image.

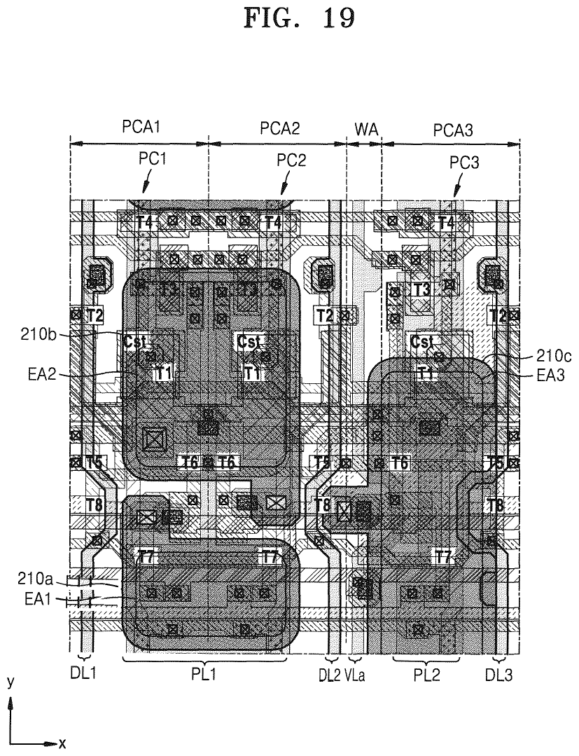

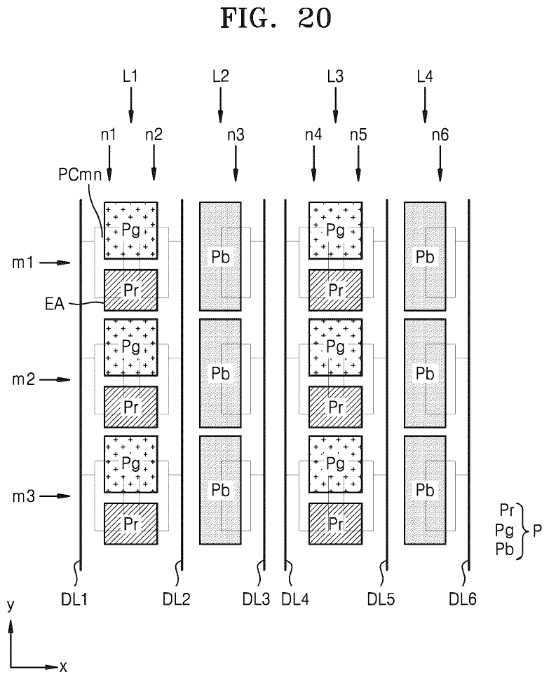

FIG. 19 is a schematic plan view illustrating a portion of a display panel, according to an embodiment. FIG. 20 is a schematic view for describing an arrangement of pixels of a display panel, according to an embodiment.

Referring to FIG. 19, the display panel 1 may include the first pixel electrode 210a connected to the first pixel circuit PC1, the second pixel electrode 210b connected to the second pixel circuit PC2, and the third pixel electrode 210c connected to the third pixel circuit PC3. The first pixel electrode 210a may define the first emission area EA1, the second pixel electrode 210b may define the second emission area EA2, and the third pixel electrode 210c may define the third emission area EA3.

The first data line DL1 may be connected to the first pixel circuit PC1, the second data line DL2 may be connected to the second pixel circuit PC2, and the third data line DL3 may be connected to the third pixel circuit PC3. The first data line DL1 may be located on a left side (−x direction) of the first pixel circuit PC1, the second data line DL2 may be located on a right side (+x direction) of the second pixel circuit PC2, and the third data line DL3 may be located on a right side (+x direction) of the third pixel circuit PC3. The first transistor T1 of the first pixel circuit PC1 (or the first gate electrode of the first transistor) and the first transistor T1 of the second pixel circuit PC2 may be located between the first data line DL1 and the second data line DL2. The first transistor T1 of the third pixel circuit PC3 may be located between the second data line DL2 and the third data line DL3. The first pixel circuit PC1 and the second pixel circuit PC2 may be symmetrical to each other with respect to an imaginary straight line extending in the second direction (y direction) along a boundary between the first pixel area PCA1 and the second pixel area PCA2.

The first driving voltage line PL1 may be located between the first data line DL1 and the second data line DL2, and the second driving voltage line PL2 may be located between the second data line DL2 and the third data line DL3. The first driving voltage line PL1 may overlap the first transistor T1 of the first pixel circuit PC1 (or the gate electrode of the first transistor) and the first transistor T1 of the second pixel circuit PC2. The second driving voltage line PL2 may overlap the first transistor T1 of the third pixel circuit PC3.

The first pixel electrode 210a and the second pixel electrode 210b may be located between the first data line DL1 and the second data line DL2, and the third pixel electrode 210c may be located between the second data line DL2 and the third data line DL3. The first pixel electrode 210a and the second pixel electrode 210b may overlap the first driving voltage line PL1 in a plan view, and the third pixel electrode 210c may overlap the second pixel circuit PC2 in a plan view. The first pixel electrode 210a and the second pixel electrode 210b may be alternately arranged along the second direction (y direction).

In a plan view, the first data line DL1 and the second data line DL2 may be spaced apart from the first pixel electrode 210a, the second pixel electrode 210b, and the third pixel electrode 210c. In a plan view, the third pixel electrode 210c may be spaced apart from the second data line DL2 and may partially overlap the third data line DL3. The first data line DL1 and the second data line DL2 may not overlap the first pixel electrode 210a, the second pixel electrode 210b, and the third pixel electrode 210c. A portion of the third data line DL3 may overlap the third pixel electrode 210c but the remaining portion of the third data line DL3 may be located outside the third pixel electrode 210c in a plan view.

According to embodiments, because an overlapping area between the pixel electrodes 210a, 210b, and 210c and the data lines DL1, DL2, and DL3 adjacent thereto is minimized, parasitic capacitance between the pixel electrodes 210a, 210b, and 210c and the data lines DL1, DL2, and DL3 adjacent thereto may be minimized. Accordingly, a change in luminance of the adjacent organic light-emitting diodes OLED (see FIG. 2) due to the data signals Dm (see FIG. 2) applied to the data lines DL1, DL2, and DL3 may be prevented or reduced.

FIG. 20 is a view for describing a stripe arrangement. In FIG. 20, the pixel P may indicate an emission area of an organic light-emitting diode included in the pixel. Referring to FIG. 20, the pixels P may be arranged in an m×L matrix in the first direction (x direction) and the second direction (y direction). Here, m and L may each be a natural number equal to or greater than 1. The pixels P arranged in the first direction (x direction) form a pixel row, and the pixels P arranged in the second direction (y direction) form a pixel column.

Each of the pixels P may include the pixel circuit PC and the organic light-emitting diode OLED (see FIG. 2). In an embodiment, the pixels P may include red pixels Pr, green pixels Pg, and blue pixels Pb.

The pixel circuits PC may be arranged in an m×n matrix in the first direction (x direction) and the second direction (y direction). Here, m and n may each be a natural number equal to or greater than 1. The pixel circuits PC arranged in the first direction (x direction) form a pixel circuit row, and the pixel circuits PC arranged in the second direction (y direction) form a pixel circuit column.

Although the pixels P are arranged in a 3×4 matrix and the pixel circuits PC are arranged in a 3×6 matrix with three rows m1, m2, m3 and six columns n1, n2, n3, n4, n5, n6 in FIG. 20 for convenience of explanation, this is only an example, and the display panel may include a larger number of pixels. A pixel circuit PCmn represents a pixel circuit PC located in the m-th row and n-th column.

Each of the data lines DL may be arranged in each pixel circuit column. The pixel circuits PC arranged in the same pixel circuit column may be connected to the same data line. The pixel circuits PC connected to the same data line may be the pixel circuits PC of the pixels P emitting light of the same color. Each of the pixel circuits PC11, PC14, PC21, PC24, PC31, and PC34 connected to the first data line DL1 and the fourth data line DL4 may form the red pixel Pr, the pixel circuits PC12, PC15, PC22, PC25, PC32, and PC35 connected to the second data line DL2 and the fifth data line DL5 may form the green pixel Pg, and the pixel circuits PC13, PC16, PC23, PC26, PC33, and PC36 connected to the third data line DL3 and the sixth data line DL6 may form the blue pixel Pb.

The pixel circuits PC11, PC21, and PC31 arranged in the first pixel circuit column n1 and the pixel circuits PC12, PC22, and PC32 arranged in the second pixel circuit column n2 may have a flip structure. The pixel circuits PC14, PC24, and PC34 arranged in the fourth pixel circuit column n4 and the pixel circuits PC15, PC25, and PC35 arranged in the fifth pixel circuit column n5 may have a flip structure.

The first data line DL1 may be located on a left side (−x direction) of the pixel circuits PC11, PC21, and PC31 arranged in the first pixel circuit column n1, and the second data line DL2 may be located on a right side (+x direction) of the pixel circuits PC12, PC22, and PC32 arranged in the second pixel circuit column n2. The third data line DL3 may be located on a right side (+x direction) of the pixel circuits PC13, PC23, and PC33 arranged in the third pixel circuit column n3. The fourth data line DLA may be located on a left side (−x direction) of the pixel circuits PC14, PC24, and PC34 arranged in the fourth pixel circuit column n4, and the fifth data line DL5 may be located on a right side (+x direction) of the pixel circuits PC15, PC25, and PC35 arranged in the fifth pixel circuit column n5. The sixth data line DL6 may be located on a right side (+x direction) of the pixel circuits PC16, PC26, and PC36 arranged in the sixth pixel circuit column n6.

The red pixel Pr and the green pixel Pg may be alternately arranged in the second direction (y direction) in odd-numbered pixel columns (for example, L1 and L3). The blue pixel Pb may be repeatedly arranged in the second direction (y direction) in even-numbered pixel columns (for example, L2 and LA). The red pixels Pr and the green pixels Pg arranged in a first pixel column L1 may be located between the first data line DL1 and the second data line DL2, the blue pixels Pb arranged in a second pixel column L2 may be located between the second data line DL2 and the third data line DL3, the red pixels Pr and the green pixels Pg arranged in a third pixel column L3 may be located between the fourth data line DL4 and the fifth data line DL5, and the blue pixels Pb arranged in a fourth pixel column L4 may be located between the fifth data line DL5 and the sixth data line DL6.

The pixels P may be located between the data lines DL1, DL2, . . . , and DL6 so that pixel electrodes and the data lines DL1, DL2, . . . , and DL6 do not overlap or have a minimum overlapping area. Accordingly, a change in luminance of the pixels P due to data signals applied to adjacent data lines DL1, DL2, . . . , and DL6 may be prevented or reduced, thereby enabling the display panel 1 according to embodiments to display a high-quality image.

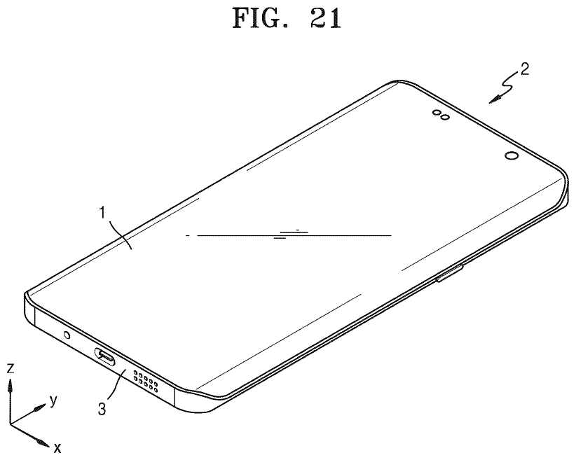

FIG. 21 is a schematic perspective view illustrating an electronic device, according to an embodiment.

Referring to FIG. 21, the display panel 1 may be provided in an electronic device 2 to display a moving image or a still image or to input and output data. For example, the display panel 1 may be accommodated in a housing 3 of the electronic device 2. The housing 3 may protect components of the electronic device 2 and fix the display panel 1.

Although the electronic device 2 is a mobile phone in FIG. 21, the disclosure is not limited thereto. The electronic device may be a portable electronic device such as a laptop, a tablet personal computer (PC), a mobile phone, a smartphone, a mobile communication terminal, electronic organizer, an electronic book, a portable multimedia player (PMP), a navigation device, or an ultra mobile PC (UMPC)

Also, the electronic device 2 may be an electronic device such as a television, a monitor, a billboard, or an Internet of things (IoT) device or may be a wearable electronic device such as a smart watch, a watch phone, a glasses-type display, or a head-mounted display (HMD). Also, the electronic device 2 according to an embodiment may be an electronic device for display such as a center information display (CID) located on an instrument panel, a center fascia, or a dashboard of a vehicle, a room mirror display replacing a side-view mirror of a vehicle, or a display screen located on the back of a front seat for entertainment for a back seat of a vehicle.

According to an embodiment as described above, a display panel for displaying a high-quality image and an electronic device including the display panel may be implemented. However, the scope of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope and as defined by the following claims.

What is claimed is:

1. A display panel comprising:
a first pixel circuit;
a second pixel circuit; and
a third pixel circuit disposed side by side along a first direction on a substrate, wherein
each of the first pixel circuit, the second pixel circuit, and the third pixel circuit comprises:
a first transistor comprising a first channel region, a first source region adjacent to the first channel region, and a first gate electrode disposed on the first channel region;
a second transistor comprising a second channel region and a second gate electrode disposed on the second channel region;
a first conductive pattern disposed below the first channel region; and
a second conductive pattern disposed on the first gate electrode,
the first source region is disposed between the first channel region and the second channel region and protrudes beyond the first conductive pattern and the second conductive pattern in the first direction in a plan view, and
the first pixel circuit and the second pixel circuit are substantially symmetrical to each other with respect to an imaginary straight line extending in a second direction intersecting the first direction.

2. The display panel of claim 1, further comprising:
a first data line electrically connected to the first pixel circuit;
a second data line electrically connected to the second pixel circuit; and
a third data line electrically connected to the third pixel circuit,
wherein the first transistor of the first pixel circuit and the first transistor of the second pixel circuit are disposed between the first data line and the second data line.

3. The display panel of claim 2, further comprising:
a first pixel electrode electrically connected to the first pixel circuit;
a second pixel electrode electrically connected to the second pixel circuit; and
a third pixel electrode electrically connected to the third pixel circuit,
wherein the first pixel electrode and the second pixel electrode are disposed between the first data line and the second data line, and the third pixel electrode is disposed between the second data line and the third data line.

4. The display panel of claim 3, wherein the first pixel electrode and the second pixel electrode are alternately disposed along the second direction.

5. The display panel of claim 3, wherein the first data line and the second data line are spaced apart from the first pixel electrode, the second pixel electrode, and the third pixel electrode in a plan view.

6. The display panel of claim 3, further comprising:
a first voltage line overlapping the first transistor of the first pixel circuit and the first transistor of the second pixel circuit; and
a second voltage line overlapping the first transistor of the third pixel circuit.

7. The display panel of claim 6, wherein
the first pixel electrode and the second pixel electrode overlap the first voltage line, and
the third pixel electrode overlaps the second voltage line.

8. The display panel of claim 6, further comprising:
a third voltage line extending in the first direction and electrically connected to the first voltage line and the second voltage line,
wherein the third voltage line is electrically connected to the first conductive pattern and the second conductive pattern.

9. The display panel of claim 3, further comprising:
an auxiliary voltage line extending in the second direction and disposed between the second data line and the first transistor of the third pixel circuit.

10. The display panel of claim 9, wherein the auxiliary voltage line is substantially symmetrical to the third data line with respect to an imaginary straight line passing through a center of the third pixel electrode.

11. A display panel comprising:
a first pixel circuit;
a second pixel circuit; and
a third pixel circuit, disposed side by side along a first direction on a substrate,
wherein each of the first pixel circuit, the second pixel circuit, and the third pixel circuit comprises:
a first conductive layer disposed on the substrate and comprising a first conductive pattern;
a first semiconductor layer disposed on the first conductive layer and comprising a first channel region, a second channel region, and a first source region disposed between the first channel region and the second channel region;
a second conductive layer disposed on the first semiconductor layer and comprising a first gate electrode overlapping the first channel region and a second gate electrode overlapping the second channel region; and
a third conductive layer disposed on the second conductive layer and comprising a second conductive pattern overlapping the first gate electrode,
the first conductive layer, the second conductive layer, and the third conductive layer include an opening portion through which the first source region is exposed in a plan view, and
the first pixel circuit and the second pixel circuit are substantially symmetrical to each other with respect to an imaginary straight line extending in a second direction intersecting the first direction.

12. The display panel of claim 11, further comprising:
a fourth conductive layer disposed on the third conductive layer and comprising a first voltage line extending in the first direction and electrically connected to the second conductive pattern; and
a fifth conductive layer disposed on the fourth conductive layer and comprising a first data line electrically connected to the first pixel circuit, a second data line electrically connected to the second pixel circuit, and a third data line electrically connected to the third pixel circuit, and
wherein the first gate electrode of the first pixel circuit and the first gate electrode of the second pixel circuit are disposed between the first data line and the second data line.

13. The display panel of claim 12, wherein
the fifth conductive layer further comprises:
a second voltage line overlapping the first gate electrode of the first pixel circuit and the first gate electrode of the second pixel circuit; and
a third voltage line extending in the second direction and overlapping the first gate electrode of the third pixel circuit, and
the first voltage line is electrically connected to the second voltage line and the third voltage line.

14. The display panel of claim 12, wherein the first voltage line is electrically connected to the first conductive pattern of the first pixel circuit.

15. The display panel of claim 12, further comprising a sixth conductive layer disposed on the fifth conductive layer and comprising a first pixel electrode electrically connected to the first pixel circuit, a second pixel electrode electrically connected to the second pixel circuit, and a third pixel electrode electrically connected to the third pixel circuit,
wherein the first pixel electrode and the second pixel electrode are disposed between the first data line and the second data line, and
the third pixel electrode is disposed between the second data line and the third data line.

16. The display panel of claim 15, wherein the first pixel electrode and the second pixel electrode are alternately disposed along the second direction.

17. The display panel of claim 15, wherein the first data line and the second data line are spaced apart from the first pixel electrode, the second pixel electrode, and the third pixel electrode in a plan view.

18. The display panel of claim 15, wherein the fifth conductive layer further comprises an auxiliary voltage line extending in the second direction and disposed between the second data line and the first gate electrode of the third pixel circuit.

19. The display panel of claim 18, wherein the auxiliary voltage line is substantially symmetrical to the third data line with respect to an imaginary straight line passing through a center of the third pixel electrode.

20. An electronic device comprising:
a display panel on which a plurality of pixels are disposed, wherein
the display panel comprises a first pixel circuit, a second pixel circuit, and a third pixel circuit, which are disposed side by side in a first direction on a substrate,
each of the first pixel circuit, the second pixel circuit, and the third pixel circuit comprises:
a first transistor comprising a first channel region, a first source region, a first drain region, and a first gate electrode disposed on the first channel region, wherein the first source region and the first drain region face each other with the first channel region disposed between the first source region and the first drain region;
a second transistor comprising a second channel region and a second gate electrode disposed on the second channel region;
a first conductive pattern disposed below the first channel region; and
a second conductive pattern disposed on the first gate electrode,
the first source region is disposed between the first channel region and the second channel region and protrudes beyond the first conductive pattern and the second conductive pattern in the first direction in a plan view, and
the first pixel circuit and the second pixel circuit are substantially symmetrical to each other with respect to an imaginary straight line extending in a second direction intersecting the first direction.
